(19) United States
(12) Patent Application Publication
(10) Pub. No.: US 2025/0311504 A1
(43) Pub. Date: Oct. 2, 2025

(54) DISPLAY DEVICE AND ELECTRONIC DEVICE

(71) Applicant: Samsung Display Co., LTD., Yongin-si (KR)

(72) Inventors: Chul Min BAE, Yongin-si (KR); Kyung Tea PARK, Yongin-si (KR); Ji Hye HAN, Yongin-si (KR)

(73) Assignee: Samsung Display Co., LTD., Yongin-si (KR)

(21) Appl. No.: 19/076,288

(22) Filed: Mar. 11, 2025

(30) Foreign Application Priority Data
Mar. 29, 2024 (KR) 10-2024-0043301

(51) Int. Cl. H10H 29/49; H01L 25/075; H10H 29/32; H10H 29/37

(52) U.S. Cl. CPC H10H 29/49; H01L 25/0753; H10H 29/32; H10H 29/37

(57) ABSTRACT

A display device includes: a substrate including a display area and a non-display area; a sub-pixel disposed in the display area; a metal line extending to be spaced apart from an emission area of the sub-pixel on a plane in the display area; and an auxiliary circuit connected to the metal line in the display area. A sub-pixel circuit of the sub-pixel and the auxiliary circuit are connected to the same data line.

### CROSS-REFERENCE TO RELATED APPLICATION(S)

The application claims priority to and benefits of Korean patent application No. 10-2024-0043301 under 35 U.S.C. § 119, filed on Mar. 29, 2024, in the Korean Intellectual Property Office, the entire contents of which are incorporated herein by reference.

### BACKGROUND

### 1. Technical Field

Embodiments relate to a display device and an electronic device.

### 2. Description of Related Art

With the development of information technologies, the importance of a display device which is a connection medium between a user and information increases. Accordingly, display devices such as a liquid crystal display device and an organic light emitting display device are increasingly used.

A display device displays an image, using pixels. In order to implement Augmented Reality (AR), Virtual Reality (VR), and a Mixed Reality (MR), it is required that a larger number of pixels are to be disposed on a small display surface in the display device.

As a distance between pixels becomes narrower, a leakage current through a common layer of adjacent pixels may be problematic.

### SUMMARY

Embodiments provide a display device and an electronic device capable of preventing a leakage current through a common layer of adjacent pixels.

However, embodiments are not limited to those set forth herein. The above and other embodiments will become more apparent to one of ordinary skill in the art to which the disclosure pertains by referencing the detailed description of the disclosure given below.

In accordance with an aspect of the disclosure, a display device may include: a substrate including a display area and a non-display area; a sub-pixel disposed in the display area; a metal line extending to be spaced apart from an emission area of the sub-pixel on a plane in the display area; and an auxiliary circuit connected to the metal line in the display area, wherein a sub-pixel circuit of the sub-pixel and the auxiliary circuit may be connected to a same data line.

The auxiliary circuit may include an auxiliary transistor including a first electrode connected to the data line and a second electrode connected to the metal line.

A gate electrode of the auxiliary transistor may be connected to the first electrode of the auxiliary transistor.

The sub-pixel may include a light emitting element. A cathode electrode of the light emitting element and the second electrode of the auxiliary transistor may be connected to a same voltage node.

The sub-pixel circuit may include: a first transistor including a gate electrode connected to a first node, a first electrode connected to a second node, and a second electrode connected to an anode electrode of the light emitting element; a second transistor including a gate electrode connected to a gate line, a first electrode connected to the data line, and a second electrode connected to the first node; and a storage capacitor including a first electrode connected to a first power voltage node and a second electrode connected to the first node.

The sub-pixel circuit may further include: a third transistor including a gate electrode connected to the second node, a first electrode connected to the first power voltage node, and a second electrode connected to the second node; and a fourth transistor including a gate electrode and a first electrode, which are connected to the anode electrode of the light emitting element, and a second electrode receiving a reference voltage.

The display device may further include a pixel defining layer defining the emission area. The metal line may be disposed on the pixel defining layer.

The sub-pixel circuit and the auxiliary circuit may be disposed in a same pixel circuit layer.

In accordance with another aspect of the disclosure, there is provided a display device including: a substrate including a display area and a non-display area; sub-pixels disposed in the display area; metal lines extending to be spaced apart from emission areas of the sub-pixels on a plane in the display area; and auxiliary circuits connected to at least one of the metal lines in the display area, wherein first sub-pixel circuits of first sub-pixels among the sub-pixels and first auxiliary circuits among the auxiliary circuits are connected to the same first data line.

The metal lines may extend in a first direction. The first data line may extend in a second direction intersecting the first direction.

The first auxiliary circuits may be connected to different metal lines.

Each of the first auxiliary circuits may be connected to two or more metal lines.

A number of the sub-pixels and a number of the auxiliary circuits may be same as each other.

A number of the sub-pixels and a number of the auxiliary circuits may be different from each other.

The number of the auxiliary circuits may be smaller than the number of the sub-pixels.

Each of the auxiliary circuits may include an auxiliary transistor including a first electrode connected to a data line and a second electrode connected to a metal line.

A gate electrode of the auxiliary transistor may be connected to the first electrode of the auxiliary transistor.

Each of the sub-pixels may include a light emitting element. A cathode electrode of the light emitting element and the second electrode of the auxiliary transistor are connected to the same voltage node.

A sub-pixel circuit of each of the sub-pixels may include: a first transistor including a gate electrode connected to a first node, a first electrode connected to a second node, and a second electrode connected to an anode electrode of the light emitting element; a second transistor including a gate electrode connected to a gate line, a first electrode connected to a data line, and a second electrode connected to the first node; and a storage capacitor including a first electrode connected to a first power voltage node and a second electrode connected to the first node.

The sub-pixel circuit may further include: a third transistor including a gate electrode connected to the second node, a first electrode connected to the first power voltage node, and a second electrode connected to the second node; and a fourth transistor including a gate electrode and a first electrode, which are connected to the anode electrode of the light emitting element, and a second electrode receiving a reference voltage.

In accordance with an aspect of the disclosure, an electronic device may include: a processor providing an image data; and a display device displaying an image based on the image data. The display device may include: a substrate including a display area and a non-display area; a sub-pixel disposed in the display area; a metal line extending to be spaced apart from an emission area of the sub-pixel on a plane in the display area; and an auxiliary circuit connected to the metal line in the display area. The sub-pixel circuit of the sub-pixel and the auxiliary circuit may be connected to a same data line.

### BRIEF DESCRIPTION OF THE DRAWINGS

Example embodiments will now be described more fully hereinafter with reference to the accompanying drawings; however, they may be embodied in different forms and should not be construed as limited to the embodiments set forth herein. Rather, these embodiments are provided so that this disclosure will be thorough and complete, and will fully convey the scope of the example embodiments to those skilled in the art.

In the drawing figures, dimensions may be exaggerated for clarity of illustration. It will be understood that when an element is referred to as being “between” two elements, it can be the only element between the two elements, or one or more intervening elements may also be present. Like reference numerals refer to like elements throughout.

FIG. 1 is a schematic block diagram illustrating an embodiment of a display device.

FIG. 2 is a schematic plan view illustrating an embodiment of a display panel shown in FIG. 1.

FIG. 3 is a schematic plan view illustrating another embodiment of the display panel shown in FIG. 1.

FIG. 4 is a schematic block diagram illustrating a sub-pixel and an auxiliary circuit.

FIG. 5 is a schematic diagram illustrating an embodiment of the sub-pixel and the auxiliary circuit.

FIG. 6 is an exploded schematic perspective view illustrating a portion of the display panel shown in FIG. 3.

FIG. 7 is a schematic plan view illustrating a relationship between sub-pixels and metal lines.

FIG. 8 is a schematic sectional view illustrating an embodiment of a light emitting structure.

FIG. 9 is a schematic sectional view illustrating another embodiment of the light emitting structure.

FIG. 10 is a schematic sectional view taken along line I-I′ shown in FIG. 7.

FIG. 11 is a schematic sectional view illustrating another embodiment of FIG. 10.

FIGS. 12 and 13 are schematic views illustrating other embodiments of the display panel shown in FIG. 3.

FIG. 14 is a schematic block diagram illustrating an embodiment of a display system.

FIG. 15 is a perspective schematic view illustrating an application example of the display system shown in FIG. 14.

FIG. 16 is a schematic view illustrating a head-mounted display device shown in FIG. 15, which is worn by a user.

### DETAILED DESCRIPTION OF THE EMBODIMENTS

In the following description, for the purposes of explanation, numerous specific details are set forth in order to provide a thorough understanding of various embodiments or implementations of the invention. As used herein, “embodiments” and “implementations” are interchangeable words that are non-limiting examples of devices or methods disclosed herein. It is apparent, however, that various embodiments may be practiced without these specific details or with one or more equivalent arrangements. Here, various embodiments do not have to be exclusive nor limit the disclosure. For example, specific shapes, configurations, and characteristics of an embodiment may be used or implemented in another embodiment.

Unless otherwise specified, the illustrated embodiments are to be understood as providing features of the invention. Therefore, unless otherwise specified, the features, components, modules, layers, films, panels, regions, and/or aspects, etc. (hereinafter individually or collectively referred to as “elements”), of the various embodiments may be otherwise combined, separated, interchanged, and/or rearranged without departing from the scope of the invention.

The use of cross-hatching and/or shading in the accompanying drawings is generally provided to clarify boundaries between adjacent elements. As such, neither the presence nor the absence of cross-hatching or shading conveys or indicates any preference or requirement for particular materials, material properties, dimensions, proportions, commonalities between illustrated elements, and/or any other characteristic, attribute, property, etc., of the elements, unless specified. Further, in the accompanying drawings, the size and relative sizes of elements may be exaggerated for clarity and/or descriptive purposes. When an embodiment may be implemented differently, a specific process order may be performed differently from the described order. For example, two consecutively described processes may be performed substantially at the same time or performed in an order opposite to the described order. Also, like reference numerals denote like elements.

When an element or a layer is referred to as being “on,” “connected to,” or “coupled to” another element or layer, it may be directly on, connected to, or coupled to the other element or layer or intervening elements or layers may be present. When, however, an element or layer is referred to as being “directly on,” “directly connected to,” or “directly coupled to” another element or layer, there are no intervening elements or layers present. To this end, the term “connected” may refer to physical, electrical, and/or fluid connection, with or without intervening elements. Further, the axis of the first direction DR1, the axis of the second direction DR2, and the axis of the third direction DR3 are not limited to three axes of a rectangular coordinate system, such as the X, Y, and Z-axes, and may be interpreted in a broader sense. For example, the axis of the first direction DR1, the axis of the second direction DR2, and the axis of the third direction DR3 may be perpendicular to one another, or may represent different directions that are not perpendicular to one another. For the purposes of this disclosure, “at least one of A and B” may be understood to mean A only, B only, or any combination of A and B. Also, “at least one of X, Y, and Z” and “at least one selected from the group consisting of X, Y, and Z” may be construed as X only, Y only, Z only, or any combination of two or more of X, Y, and Z. As used herein, the term “and/or” includes any and all combinations of one or more of the associated listed items.

Although the terms “first,” “second,” etc. may be used herein to describe various types of elements, these elements should not be limited by these terms. These terms are used to distinguish one element from another element. Thus, a first element discussed below could be termed a second element without departing from the teachings of the disclosure.

Spatially relative terms, such as “beneath,” “below,” “under,” “lower,” “above,” “upper,” “over,” “higher,” “side” (e.g., as in “sidewall”), and the like, may be used herein for descriptive purposes, and, thereby, to describe one element's relationship to another element(s) as illustrated in the drawings. Spatially relative terms are intended to encompass different orientations of an apparatus in use, operation, and/or manufacture in addition to the orientation depicted in the drawings. For example, if the apparatus in the drawings is turned over, elements described as “below” or “beneath” other elements or features would then be oriented “above” the other elements or features. Thus, the term “below” can encompass both an orientation of above and below. Furthermore, the apparatus may be otherwise oriented (e.g., rotated 90 degrees or at other orientations), and, as such, the spatially relative descriptors used herein should be interpreted accordingly.

The terminology used herein is for the purpose of describing particular embodiments and is not intended to be limiting. As used herein, the singular forms, “a,” “an,” and “the” are intended to include the plural forms as well, unless the context clearly indicates otherwise. Moreover, the terms “comprises,” “comprising,” “includes,” and/or “including,” when used in this specification, specify the presence of stated features, integers, steps, operations, elements, components, and/or groups thereof, but do not preclude the presence or addition of one or more other features, integers, steps, operations, elements, components, and/or groups thereof. It is also noted that, as used herein, the terms “substantially,” “about,” and other similar terms, are used as terms of approximation and not as terms of degree, and, as such, are utilized to account for inherent deviations in measured, calculated, and/or provided values that would be recognized by one of ordinary skill in the art.

Various embodiments are described herein with reference to sectional and/or exploded illustrations that are schematic illustrations of embodiments and/or intermediate structures. As such, variations from the shapes of the illustrations as a result, for example, of manufacturing techniques and/or tolerances, are to be expected. Thus, embodiments disclosed herein should not necessarily be construed as limited to the particular illustrated shapes of regions, but are to include deviations in shapes that result from, for instance, manufacturing. In this manner, regions illustrated in the drawings may be schematic in nature and the shapes of these regions may not reflect actual shapes of regions of a device and, as such, are not necessarily intended to be limiting.

As customary in the field, some embodiments are described and illustrated in the accompanying drawings in terms of functional blocks, units, and/or modules. Those skilled in the art will appreciate that these blocks, units, and/or modules are physically implemented by electronic (or optical) circuits, such as logic circuits, discrete components, microprocessors, hard-wired circuits, memory elements, wiring connections, and the like, which may be formed using semiconductor-based fabrication techniques or other manufacturing technologies. In the case of the blocks, units, and/or modules being implemented by microprocessors or other similar hardware, they may be programmed and controlled using software (e.g., microcode) to perform various functions discussed herein and may optionally be driven by firmware and/or software. It is also contemplated that each block, unit, and/or module may be implemented by dedicated hardware, or as a combination of dedicated hardware to perform some functions and a processor (e.g., one or more programmed microprocessors and associated circuitry) to perform other functions. Also, each block, unit, and/or module of some embodiments may be physically separated into two or more interacting and discrete blocks, units, and/or modules without departing from the scope of the invention. Further, the blocks, units, and/or modules of some embodiments may be physically combined into more complex blocks, units, and/or modules without departing from the scope of the invention.

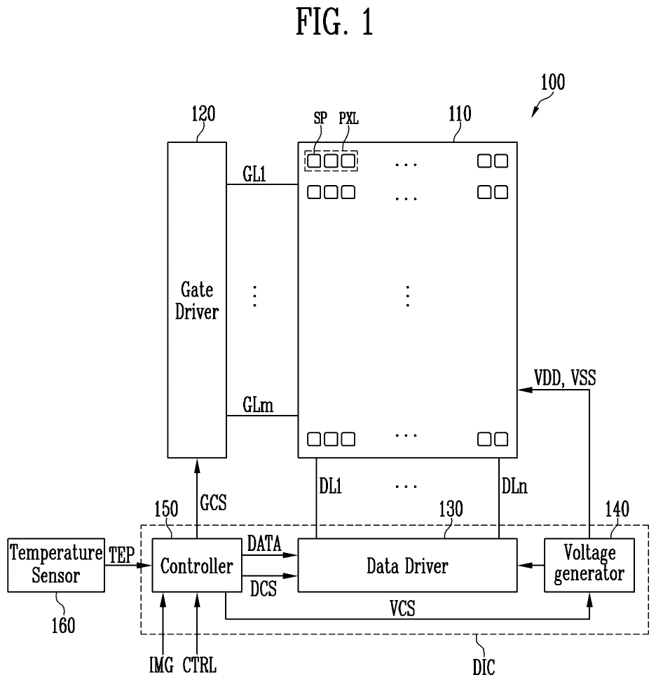

FIG. 1 is a schematic block diagram illustrating an embodiment of a display device.

Referring to FIG. 1, the display device 100 may include a display panel 110, a gate driver 120, a data driver 130, a voltage generator 140, and a controller 150.

The display panel 110 may include sub-pixels SP. The sub-pixels SP may be connected to the gate driver 120 through first to m-th gate lines GL1 to GLm. The sub-pixels SP may be connected to the data driver 130 through first to n-th data lines DL1 to DLn.

Each of the sub-pixels SP may include at least one light emitting element that generates light. Accordingly, each of the sub-pixels SP may generate light of a specific color such as red, green, blue, cyan, magenta or yellow. Two or more sub-pixels among the sub-pixels SP may constitute a pixel (e.g., single pixel) PXL. For example, three sub-pixels SP may constitute the pixel PXL as shown in FIG. 1.

The gate driver 120 may be connected to the sub-pixels SP arranged in a row direction through the first to m-th gate lines GL1 to GLm. The gate driver 120 may output gate signals to the first to m-th gate lines GL1 to GLm in response to a gate control signal GCS. In embodiments, the gate control signal GCS may include a start signal indicating a start of each frame, a horizontal synchronization signal for outputting gate signals in synchronization with timings at which data signals are applied, and the like.

The gate driver 120 may be disposed at a side of the display panel 110. However, embodiments are not limited thereto. For example, the gate driver 120 may be divided into two or more drivers which are physically and/or logically divided, and these drivers may be disposed at the side of the display panel 110 and another side of the display panel 110, which is opposite to the side. For example, in some embodiments, the gate driver 120 may be disposed in various forms at the periphery of the display panel 110.

The data driver 130 may be connected to the sub-pixels SP arranged in a column direction through the first to n-th data lines DL1 to DLn. The data driver 130 may receive image data DATA and a data control signal DCS from the controller 150. The data driver 130 may operate in response to the data control signal DCS. In embodiments, the data control signal DCS may include a source start pulse, a source shift clock, a source output enable signal, and the like.

The data driver 130 may apply data signals having grayscale voltages corresponding to the image data DATA to the first to n-th data lines DL1 to DLn by using voltages from the voltage generator 140. In case that a gate signal is applied to each of the first to m-th gate lines GL1 to GLm, data signals corresponding to the image data DATA may be applied to the data line DL1 to DLm. Accordingly, corresponding sub-pixels SP may generate light corresponding to the data signals. Accordingly, an image may be displayed on the display panel 110.

In embodiments, the gate driver 120 and the data driver 130 may include complementary metal-oxide semiconductor (CMOS) circuit elements.

The voltage generator 140 may operate in response to a voltage control signal VCS from the controller 150. The voltage generator 140 may generate a plurality of voltages and provide the generated voltages to components of the display device 100. For example, the voltage generator 140 may generate a plurality of voltages by receiving an input voltage from the outside of the display device 100, adjusting the received voltage, and regulating the adjusted voltage.

The voltage generator 140 may generate a first power voltage VDD and a second power voltage VSS, and the generated first and second power voltages VDD and VSS may be provided to the sub-pixels SP. The first power voltage VDD may have a relatively high voltage level, and the second power voltage VSS may have a voltage level lower than the voltage level of the first power voltage VDD. In other embodiments, the first power voltage VDD or the second power voltage VSS may be provided by an external device of the display device 100.

Besides, the voltage generator 140 may generate various voltages. For example, the voltage generator 140 may generate an initialization voltage applied to the sub-pixels SP. For example, a selected reference voltage may be applied to the first to n-th data lines DL1 to DLn in a sensing operation for sensing electrical characteristics of transistors and/or light emitting elements of the sub-pixels SP, and the voltage generator 140 may generate the reference voltage.

The controller 150 may control overall operations of the display device 100. The controller 150 may receive, from the outside, input image data IMG and a control signal CTRL for controlling display thereof. The controller 150 may provide the gate control signal GCS, the data control signal DCS, and the voltage control signal VCS in response to the control signal CTRL.

The controller 150 may convert the input image data IMG to be suitable for the display device 100 or the display panel 110, thereby outputting the image data DATA. In embodiments, the controller 150 may align the input image data IMG to be suitable for the sub-pixels SP, thereby outputting the image data DATA.

Two or more components among the data driver 130, the voltage generator 140, and the controller 150 may be mounted on an integrated circuit. As shown in FIG. 1, the data driver 130, the voltage generator 140, and the controller 150 may be included in a driver integrated circuit DIC. The data driver 130, the voltage generator 140, and the controller 150 may be components functionally divided in a driver integrated circuit DIC. In other embodiments, at least one of the data driver 130, the voltage generator 140, and the controller 150 may be provided as a component distinguished from the driver integrated circuit DIC.

In some embodiments, the display device 100 may include at least one temperature sensor 160. The temperature sensor 160 may sense a temperature at the periphery thereof and generate temperature data TEP indicating the sensed temperature. In embodiments, the temperature sensor 160 may be disposed to be adjacent to the display panel 110 and/or the driver integrated circuit DIC.

The controller 150 may control various operations of the display device 100 in response to the temperature data TEP. In embodiments, the controller 150 may adjust the luminance of an image output from the display panel 110 in response to the temperature data TEP. For example, the controller 150 may control components such as the data driver 130 and/or the voltage generator 140, thereby adjusting data signals and the first and second power voltages VDD and VSS.

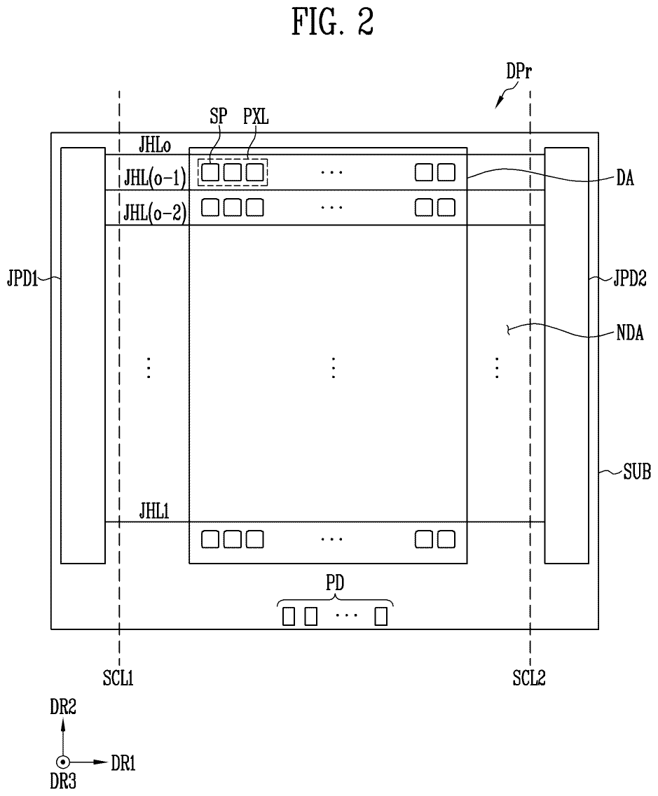

FIG. 2 is a schematic plan view illustrating an embodiment of the display panel shown in FIG. 1.

Referring to FIG. 2, an embodiment DPr of the display panel 110 shown in FIG. 1 may include a display area DA and a non-display area NDA. The display panel DPr may display an image through the display area DA. The non-display area NDA may be disposed at the periphery of the display area DA.

The display panel DPr may include a substrate SUB, sub-pixels SP, a first metal pad JPD1, a second metal pad JPD2, metal lines JHL1 to JHLo, and pads PD.

In case that the display panel DPr is used as a display screen of a Head Mounted Display (HMD), a Virtual Reality (VR) device, a Mixed Reality (MR) device, an Augmented Reality (AR) device, and the like, the display panel DPr may be positioned very close to eyes of a user. The sub-pixels SP having a relatively high degree of integration may be required. In order to increase the degree of integration of the sub-pixels SP, the substrate SUB may be provided as a silicon substrate. The sub-pixels SP and/or the display panel DPr may be formed on the substrate SUB as the silicon substrate. The display device 100 (see FIG. 1) including the display panel DPr formed on the substrate SUB as the silicon substrate may be designated as an OLED on Silicon (OLEDoS) display device.

The sub-pixels SP may be disposed in the display area DA on the substrate SUB. The sub-pixels SP may be arranged in a matrix form along a first direction DR1 and a second direction DR2 intersecting the first direction DR1. However, embodiments are not limited thereto. For example, the sub-pixels SP may be arranged in a zigzag form along the first direction DR1 and the second direction DR2. For example, the sub-pixels SP may be disposed in a PENTILE™ form. The first direction DR1 may be a row direction, and the second direction DR2 may be a column direction. Two or more sub-pixels among the sub-pixels SP may constitute a pixel (e.g., single pixel) PXL.

The substrate SUB may include the display area DA and the non-display area NDA. A component for controlling the sub-pixels SP may be disposed in the non-display area NDA on the substrate SUB. For example, lines connected to the sub-pixels SP, such as the first to m-th gate lines GL1 to GLm and the first to n-th data lines DL1 to DLn, which are shown in FIG. 1, may be spatially efficiently disposed in the non-display area NDA.

The first metal pad JPD1 may be positioned in the non-display area NDA. The first metal pad JPD1 may have a substantially rectangular shape in which long sides extend in the second direction DR2 and short sides extend in the first direction DR1. A length of the long side may be similar to a length of the display area DA in the second direction DR2. The first metal pad JPD1 may include at least one metal material. For example, the first metal pad JPD1 may include a material having a high resistivity and a high melting point, such as molybdenum (Mo), titanium (Ti) or titanium nitride (TiN). The first metal pad JPD1 may be positioned in the opposite direction of the first direction DR1 from the display area DA.

The second metal pad JPD2 may be positioned in the non-display area NDA, and be positioned in the first direction DR1 from the first metal pad JPD1. The second metal pad JPD2 may have a substantially rectangular shape in which long sides extend in the second direction DR2 and short sides extend in the first direction DR1. A length of the long side may be similar to the length of the display area DA in the second direction DR2. The second metal pad JPD2 may include at least one metal material. For example, the second metal pad JPD2 may include a material having a high resistivity and a high melting point, such as molybdenum (Mo), titanium (Ti) or titanium nitride (TiN). The second metal pad JPD2 may be positioned in the first direction DR1 from the display area DA.

The metal lines JHL1 to JHLo may connect the first metal pad JPD1 and the second metal pad JPD2 to each other. Here, o may be an integer greater than 1. Each of the metal lines JHL1 to JHLo may extend in the first direction DR1 not to overlap sub-pixels SP. Each of the metal lines JHL1 to JHLo may not overlap the sub-pixels SP may mean that each of the metal lines JHL1 to JHLo may not overlap emission areas of the sub-pixels SP. For example, the metal lines JHL1 to JHLo may extend to be spaced apart from the emission areas of the sub-pixels SP on a plane. The metal lines JHL1 to JHLo may be arranged in parallel to each other in the second direction DR2. End portions of the metal lines JHL1 to JHLo may be connected to the first metal pad JPD1, and the other end portions of the metal lines JHL1 to JHLo may be connected to the second metal pad JPD2. For example, the metal lines JHL1 to JHLo may include a material having a high resistivity and a high melting point, such as molybdenum (Mo), titanium (Ti) or titanium nitride (TiN). The metal lines JHL1 to JHLo, the first metal pad JPD1, and the second metal pad JPD2 may be simultaneously formed through the same process or be formed at different times through different processes.

In case that a first voltage is applied to the first metal pad JPD1 and a second voltage different from the first voltage is applied to the second metal pad JPD2, heat due to Joule heating may be generated in the metal lines JHL1 to JHLo. The first voltage may be a single pulse, and include a plurality of pulses. Due to the generated heat, an organic material adjacent to the metal lines JHL1 to JHLo may be sublimated. For example, the second voltage may be a low voltage or a ground voltage.

A virtual first scribing line SCL1 may extend in the second direction DR2 between the first metal pad JPD1 and the display area DA. The first scribing line SCL1 may traverse (or cross) the metal lines JHL1 to JHLo. A virtual second scribing line SCL2 may extend in the second direction DR2 between the second metal pad JPD2 and the display area DA. The second scribing line SCL2 may traverse (or cross) the metal lines JHL1 to JHLo.

After a Joule heating process, as the display panel DPr is cut along the scribing lines SCL1 and SCL2, the first metal pad JPD1 and the second metal pad JPD2 may not exist in a final product. In another embodiment, as the display panel DPr is not cut along the scribing lines SCL1 and SCL2, the first metal pad JPD1 and the second metal pad JPD2 may exist in a final product.

At least one of the gate driver 120, the data driver 130, the voltage generator 140, the controller 150, and the temperature sensor 160, which are shown in FIG. 1, may be integrated in the non-display area NDA of the display panel DPr. In embodiments, the gate driver 120 shown in FIG. 1 may be mounted on the display panel DPr, and may be disposed in the non-display area NDA. In other embodiments, the gate driver 120 may be implemented as an integrated circuit distinguished from the display panel DPr. In embodiments, the temperature sensor 160 may be disposed in the non-display area NDA to sense a temperature of the display panel DPr.

The pads PD may be disposed in the non-display area NDA on the substrate SUB. The pads PD may be electrically connected to the sub-pixels SP through the lines. For example, the pads PD may be connected to the sub-pixels SP through the first to n-th data lines DL1 to DLn.

The pads PD may interface the display panel DPr with other components of the display device 100 (see FIG. 1). In embodiments, voltages and signals, which are necessary for operations of components included in the display panel DPr, may be provided from the driver integrated circuit DIC shown in FIG. 1 through the pads PD. For example, the first to n-th data lines DL1 to DLn may be connected to the driver integrated circuit DIC through the pads PD. For example, the first and second power voltages VDD and VSS may be received from the driver integrated circuit DIC through the pads PD. In case that the gate driver 120 is mounted in the display panel DPr, the gate control signal GCS may be transmitted from the driver integrated circuit DIC to the gate driver 120 through the pads PD.

In embodiments, a circuit board may be electrically connected to the pads PD, using a conductive adhesive member such as an anisotropic conductive film. The circuit board may be a Flexible Printed Circuit Board (FPCB) or a flexible film, which has a flexible material. The driver integrated circuit DIC may be mounted on the circuit board to be electrically connected to the pads PD.

In embodiments, the display area DA may have various shapes. The display area DA may have closed-loop shapes including linear sides and/or curved sides. For example, the display area DA may have shapes such as a polygon, a circle, a semicircle, and an ellipse.

In embodiments, the display panel DPr may have a flat display surface. In other embodiments, the display panel DPr may at least partially have a round display surface. In embodiments, the display panel DPr may be bendable, foldable or rollable. The display panel DPr and/or the substrate SUB may include materials having flexibility.

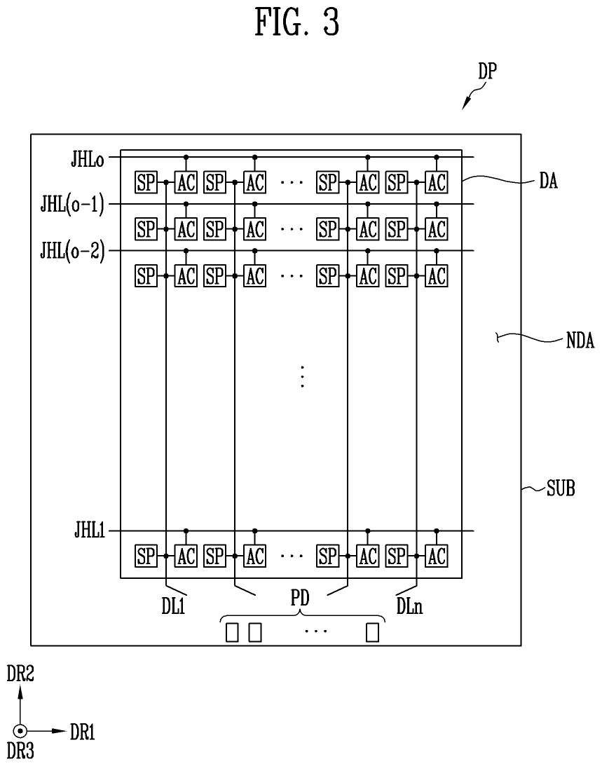

FIG. 3 is a schematic plan view illustrating another embodiment of the display panel shown in FIG. 1.

Unlike the display panel DPr shown in FIG. 2, a display panel DP shown in FIG. 3 may not include the first metal pad JPD1 and the second metal pad JPD2.

The display panel DP may include an auxiliary circuits AC. Each of the auxiliary circuits AC may be connected to at least one of metal lines JHL1 to JHLo in a display area DA. Also, each of the auxiliary circuits AC may be connected at least one of data lines DL1 to DLn in the display area DA. The data lines DL1 to DLn may extend in the second direction DR2 intersecting the first direction DR1. For example, the second direction DR2 may be a direction perpendicular to the first direction DR1.

First sub-pixel circuits of first sub-pixels among sub-pixels SP and first auxiliary circuits among the auxiliary circuits AC may be connected to the same first data line DL1. The first sub-pixels may be arranged in the second direction DR2. The first auxiliary circuits may be arranged in the second direction DR2. The first auxiliary circuits may be connected to different metal lines JHL1 to JHLo.

Similarly, n-th sub-pixel circuits of n-th sub-pixels among the sub-pixels SP and n-th auxiliary circuits among the auxiliary circuits AC may be connected to the same n-th data line DLn. The n-th sub-pixels may be arranged in the second direction DR2. The n-th auxiliary circuits may be arranged in the second direction DR2. The n-th auxiliary circuits may be connected to different metal lines JHL1 to JHLo.

The number, positions, and connection relationship of the auxiliary circuits AC may be variously set. In the embodiment shown in FIG. 3, a number of the auxiliary circuits AC may be equal to a number of the sub-pixels SP. Auxiliary circuits AC in a row unit may be connected to the same metal line. Auxiliary circuits AC in a column unit may be connected to the same data line. A density of the auxiliary circuits AC may be constant throughout the entire display area DA. The number, positions, and connection relationship of the auxiliary circuits AC may be variously changed.

The data lines DL1 to DLn connected to the auxiliary circuits AC may be connected to pads PD. In a Joule heating process, a voltage applied to the pads PD may be applied to the metal lines JHL1 to JHLo through the data lines DL1 to DLn and the auxiliary circuits AC.

In accordance with the embodiment shown in FIG. 3, the display panel DP may not include the first metal pad JPD1 and the second metal pad JPD2, so that various effects may be exhibited. First, a necessary area on a mother substrate for forming the display panel DP may be decreased. For example, a voltage drop phenomenon (IR drop) on the metal lines JHL1 to JHLo, which occurs in a process in which a current flows from the first metal pad JPD1 to the second metal pad JPD2, may not appear.

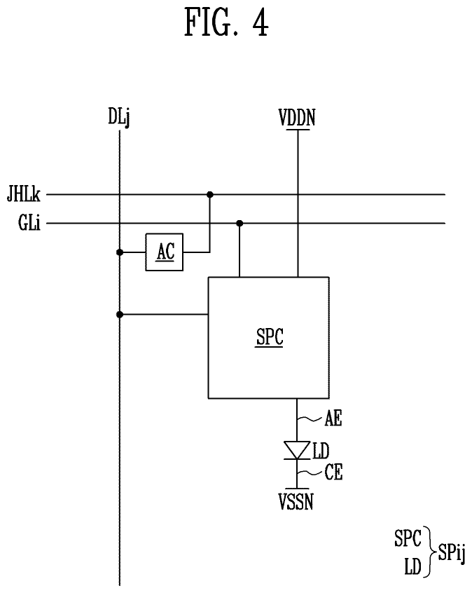

FIG. 4 is a schematic block diagram illustrating a sub-pixel and an auxiliary circuit.

Referring to FIG. 4, a sub-pixel SPij arranged on an i-th row (i is an integer greater than or equal to 1 and smaller than or equal to m) and a j-th column (j is an integer greater than or equal to 1 and smaller than or equal to n) among sub-pixels SP is illustrated. The sub-pixel SPij may include a sub-pixel circuit SPC and a light emitting element LD.

Also, referring to FIG. 4, an auxiliary circuit AC is illustrated. The auxiliary circuit AC may be connected between at least one JHLk of metal lines JHL1 to JHLo and a data line DLj.

The light emitting element LD may be connected between a first power voltage node VDDN and a second power voltage node VSSN. The first power voltage node VDDN may be a node transferring the first power voltage VDD shown in FIG. 1, and the second power voltage node VSSN may be a node transferring the second power voltage VSS shown in FIG. 1.

An anode electrode AE of the light emitting element LD may be connected to the first power voltage node VDDN through the sub-pixel circuit SPC, and a cathode electrode CE may be connected to the second power voltage node VSSN. For example, the anode electrode AE of the light emitting element LD may be connected to the first power voltage node VDDN through one or more transistors included in the sub-pixel circuit SPC.

The sub-pixel circuit SPC may be connected to an i-th gate line GLi among the first to m-th gate lines GL1 to GLm shown in FIG. 1 and a j-th data line DLj among the first to n-th data lines DL1 to DLn shown in FIG. 1. The sub-pixel circuit SPC may control the light emitting element LD according to signals received through these signal lines.

The sub-pixel circuit SPC may operate in response to a gate signal received through the i-th gate line GLi. The sub-pixel circuit SPC may receive a data signal through the j-th data line DLj. For example, the sub-pixel circuit SPC may store a voltage corresponding to the data signal in response to the gate signal. The light emitting clement LD may generate light with a luminance corresponding to the data signal, based on the voltage stored in the sub-pixel circuit SPC.

The auxiliary circuit AC may supply a voltage to the metal line JHLk, based on a voltage applied to the data line DLj, in a Joule heating process. However, the auxiliary circuit AC may not operate in case that the display device 100 displays an image. For example, in case that the display device 100 displays an image, the voltage applied to the data line DLj may be blocked by the auxiliary circuit AC. Therefore, the voltage applied to the data line DLj may not be applied to the metal line JHLk.

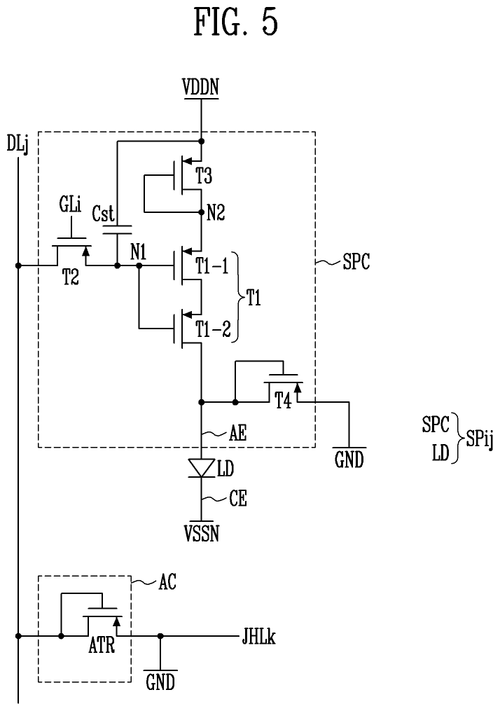

FIG. 5 is a diagram illustrating an embodiment of the sub-pixel and the auxiliary circuit.

Referring to FIG. 5, a sub-pixel SPij may include a sub-pixel circuit SPC and a light emitting element LD. The sub-pixel circuit SPC may include first to fourth transistors T1 to T4 and a storage capacitor Cst.

A gate electrode of the first transistor T1 may be connected to a first node N1, a first electrode of the first transistor T1 may be connected to a second node N2, and a second electrode of the first transistor T1 may be connected to an anode electrode AE of the light emitting element LD. The first transistor T1 may include sub-transistors T1-1 and T1-2 connected to each other in series. The first transistor T1 may be a driving transistor.

A gate electrode of the second transistor T2 may be connected to an i-th gate line GLi, a first electrode of the second transistor T2 may be connected to a j-th data line DLj, and a second electrode of the second transistor T2 may be connected to the first node N1.

A gate electrode of the third transistor T3 may be connected to the second node N2, a first electrode of the third transistor T3 may be connected to a first power voltage node VDDN, and a second electrode of the third transistor T3 may be connected to the second node N2.

A gate electrode and a first electrode of the fourth transistor T4 may be connected to the anode electrode AE of the light emitting element LD, and a second electrode of the fourth transistor T4 may receive a reference voltage GND. The reference voltage GND may be set lower than the first power voltage VDD. In an embodiment, the reference voltage GND may be equal to the second power voltage VSS. In another embodiment, the reference voltage GND may be different from the second power voltage VSS.

A first electrode of the storage capacitor Cst may be connected to the first power voltage node VDDN, and a second electrode of the storage capacitor Cst may be connected to the first node N1.

The light emitting element LD may include the anode electrode AE, a cathode electrode CE, and a light emitting structure. The light emitting structure may be disposed between the anode electrode AE and the cathode electrode CE.

In case that a gate signal having a turn-on level (e.g., a low level) is applied to the i-th gate line GLi, the second transistor T2 may be turned on. A data signal applied to the j-th data line DLj may be applied to the first node N1 through the second transistor T2. The storage capacitor Cst may maintain a voltage of the data signal. The first transistor T1 may determine an amount of driving current flowing from the first power voltage node VDDN to a second power voltage node VSSN, corresponding to the voltage of the data signal. The light emitting element LD may emit light with a luminance corresponding to the amount of driving current.

The third transistor T3 and the fourth transistor T4 may be diode-connected transistors, and may limit a direction of current such that the current flows in a reverse direction. In some embodiments, the third transistor T3 and the fourth transistor T4 may be removed in the sub-pixel circuit SPC. In case that the third transistor T3 is removed, the second node N2 may be connected (e.g., directly connected) to the first power voltage node VDDN.

An auxiliary circuit AC may include an auxiliary transistor ATR. A first electrode of the auxiliary transistor ATR may be connected to the data line DLj, and a second electrode of the auxiliary transistor ATR may be connected to a metal line JHLk. For example, a gate electrode of the auxiliary transistor ATR may be connected to the first electrode of the auxiliary transistor ATR. For example, the auxiliary transistor ATR may be diode-connected.

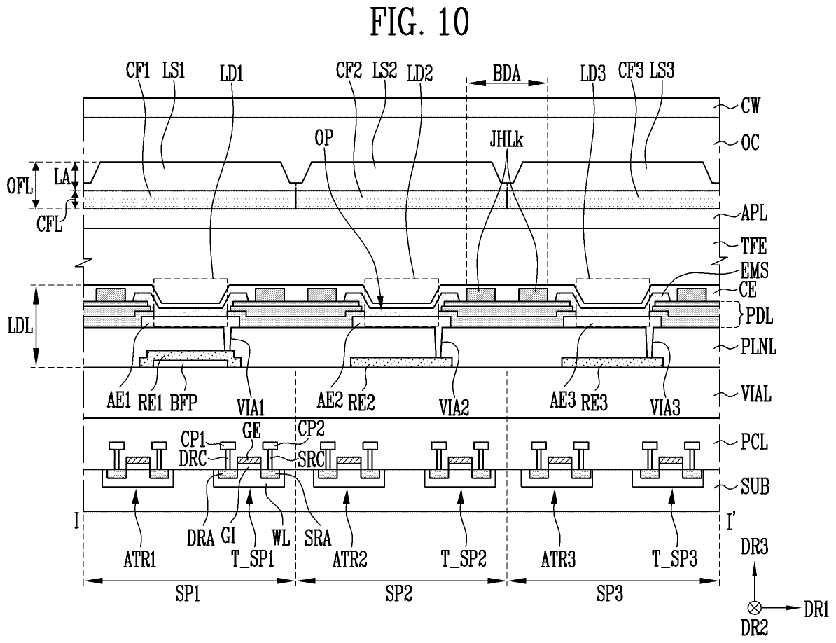

The second electrode of the auxiliary transistor ATR may receive the reference voltage GND. In an embodiment, the reference voltage GND may be equal to the second power voltage VSS applied to the cathode electrode CE of the light emitting element LD. For example, the cathode electrode CE of the light emitting element LD and the second electrode of the auxiliary transistor ATR may be connected to the same voltage node. For example, after a Joule heating process, as the cathode electrode CE is formed on the metal line JHLk having an exposed upper portion, the metal line JHLk and the cathode electrode CE may be connected to each other (see FIG. 10).

In another embodiment, the reference voltage GND may be different from the second power voltage VSS. For example, a ground voltage GND applied to the second electrode of the auxiliary transistor ATR may be equal to or different from a ground voltage GND applied to the second electrode of the fourth transistor T4.

In the Joule heating process, a first voltage applied to the data line DLj may be higher than a voltage applied to the metal line JHLk. For example, a difference between the first voltage of the data line DLj and the voltage of the metal line JHLk may be higher than a breakdown voltage of the auxiliary transistor ATR. Therefore, a current may flow toward the metal line JHLk from the data line DLj, and peripheral organic materials may be sublimated as heat is generated in the metal line JHLk.

In an embodiment, in the Joule heating process, a second voltage may be applied to at least another data line (hereinafter, referred to as a second data line). The second voltage may be lower than the first voltage. For example, the second voltage may be a ground voltage. A second auxiliary transistor may be connected between the second data line and the metal line JHLk. A connection structure may be the same as shown in FIG. 5, and therefore, overlapping descriptions will be omitted. Therefore, a current path toward the second voltage applied to the second data line from the first voltage applied to the data line DLj may be formed. For example, referring back to FIG. 3, the first voltage may be applied to a pad PD connected to a data line DL1, and the second voltage may be applied to a pad PD connected to a data line DLn. A current path including the data line DL1, the metal lines JHL1 to JHLo, and the data line DLn may be formed.

In case that the display device 100 displays an image, a difference between the voltage (e.g., the data signal) of the data line DLj and the reference voltage GND may be lower than the breakdown voltage of the auxiliary transistor ATR. Thus, the current may be prevented from flowing toward the metal line JHLk from the data line DLj.

The first to fourth transistors T1 to T4 and the auxiliary transistor ATR may be P-type transistors. Each of the first to fourth transistors T1 to T4 may be a Metal Oxide Silicon Field Effect Transistor (MOSFET). However, embodiments are not limited thereto. For example, at least one of the first to fourth transistors T1 to T4 may be replaced with an N-type transistor.

In embodiments, the transistors T1 to T4 and ATR may include an amorphous silicon semiconductor, a monocrystalline silicon semiconductor, a polycrystalline silicon semiconductor, an oxide semiconductor, and the like.

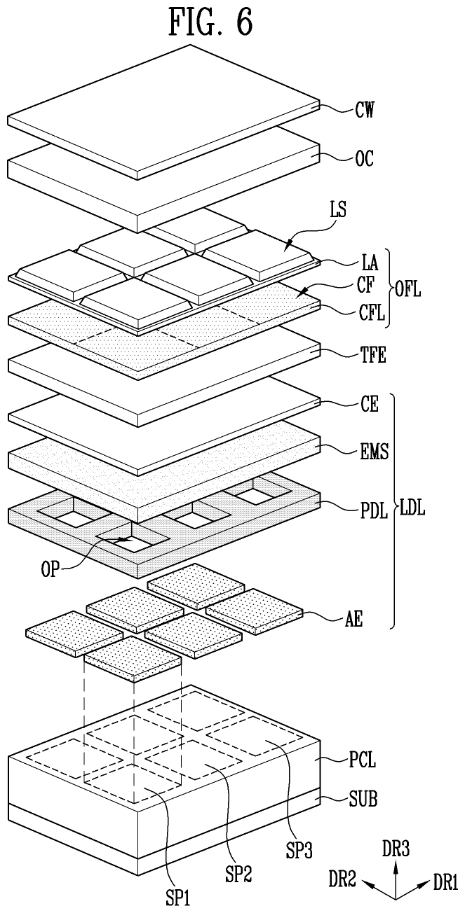

FIG. 6 is an exploded schematic perspective view illustrating a portion of the display panel shown in FIG. 3.

The display panel DP may include a substrate SUB, a pixel circuit layer PCL, a light emitting element layer LDL, an encapsulation layer TFE, an optical functional layer OFL, an overcoat layer OC, and a cover window CW.

In embodiments, the substrate SUB may include a silicon wafer substrate formed using a semiconductor process. The substrate SUB may include a semiconductor material suitable for forming circuit elements. For example, the semiconductor material may include silicon, germanium, and/or silicon-germanium. The substrate SUB may be provided from a bulk wafer, an epitaxial layer, a Silicon On Insulator (SOI) layer, a Semiconductor On Insulator (SeOI) layer, or the like. In other embodiments, the substrate SUB may include a glass substrate. In still other embodiments, the substrate SUB may include a polyimide (PI) substrate.

The pixel circuit layer PCL may be disposed on the substrate SUB. The substrate SUB and/or the pixel circuit layer PCL may include insulating layers and conductive patterns disposed between the insulating layers. The conductive patterns of the pixel circuit layer PCL may function as at least some of circuit elements, lines, and the like. The conductive patterns may include copper, but embodiments are not limited thereto.

The circuit elements may include a sub-pixel circuit SPC (see FIG. 3) of each of first to third sub-pixels SP1, SP2, and SP3. The circuit elements may include auxiliary transistors ATR of auxiliary circuits AC. For example, the sub-pixel circuit SPC and the auxiliary circuit AC may be positioned in the same pixel circuit layer PCL. The sub-pixel circuit SPC may include transistors and at least one capacitor. Each transistor may include a semiconductor portion including a source region, a drain region, and a channel region, and a gate electrode overlapping the semiconductor portion. In embodiments, in case that the substrate SUB is provided as a silicon substrate, the semiconductor portion may be included in the substrate SUB, and the gate electrode may be included as a conductive pattern of the pixel circuit layer PCL in the pixel circuit layer PCL. In embodiments, in case that the substrate SUB is provided as a glass substrate or a PI substrate, the semiconductor portion and the gate electrode may be included in the pixel circuit layer PCL. Each capacitor may include electrodes, which are spaced apart from each other. For example, each capacitor may include electrodes spaced apart from each other on a plane defined by the first and second directions DR1 and DR2. For example, the capacitor may include electrodes spaced apart from each other in a third direction DR3 with an insulating layer interposed therebetween.

The lines of the pixel circuit layer PCL may include signal lines, e.g., a gate line, an emission control line, a data line, and the like, which are connected to each of sub-pixels. The lines may further include a line connected to the first power voltage node VDDN shown in FIG. 3. The lines may further include a line connected to the second power voltage node VSSN shown in FIG. 3.

The light emitting element layer LDL may include anode electrodes AE, a pixel defining layer PDL, a light emitting structure EMS, and a cathode electrode CE.

The anode electrodes AE may be disposed on the pixel circuit layer PCL. The anode electrodes AE may be in contact with the circuit elements of the pixel circuit layer PCL. The anode electrodes AE may include an opaque conductive material capable of reflecting light, but embodiments are not limited thereto.

The pixel defining layer PDL may be disposed on the anode electrodes AE. The pixel defining layer PDL may include an opening OP exposing a portion of each of the anode electrodes AE. The opening OP of the pixel defining layer PDL may be understood as an emission area corresponding to each of the first to third sub-pixels SP1 to SP3.

In embodiments, the pixel defining layer PDL may include an inorganic material. The pixel defining layer PDL may include a plurality of stacked inorganic layers. For example, the pixel defining layer PDL may include silicon oxide (SiOₓ) and silicon nitride (SiNₓ). In other embodiments, the pixel defining layer PDL may include an organic material. However, the material of the pixel defining layer PDL is not limited thereto.

The light emitting structure EMS may be disposed on the anode electrodes AE exposed by the openings OP of the pixel defining layer PDL. The light emitting structure EMS may include a light emitting layer that generates light, an electron transport layer that transports electrons, a hole transport layer that transports holes, and the like.

In embodiments, the light emitting structure (or light emitting member) EMS may fill the opening OP of the pixel defining layer PDL, and may be disposed (e.g., entirely disposed) on the top (or upper surface) of the pixel defining layer PDL. In other words, the light emitting structure EMS may extend throughout the first to third sub-pixels SP1 to SP3. At least some of the layers in the light emitting structure EMS may be cut, curved or removed at boundaries between the sub-pixels. However, embodiments are not limited thereto. For example, portions of the light emitting structure EMS, which correspond to the sub-pixels, may be separated from each other, and each of the portions may be disposed in the opening OP of the pixel defining layer PDL.

The cathode electrode CE may be disposed on the light emitting structure EMS. The cathode electrode CE may extend throughout the sub-pixels. For example, the cathode electrode CE may be provided as a common electrode for the sub-pixels.

The cathode electrode CE may be a thin metal layer having a thickness to a degree to which light emitted from the light emitting structure EMS may be transmitted therethrough. The cathode electrode CE may be formed of a metal material to have a relatively thin thickness or be formed of a transparent conductive material. In embodiments, the cathode electrode CE may include at least one of various transparent conductive materials including indium tin oxide, indium zinc oxide, indium tin zinc oxide, aluminum zinc oxide, gallium zinc oxide, zinc tin oxide, and gallium tin oxide. In other embodiments, the cathode electrode CE may include at least one of silver (Ag), magnesium (Mg), and mixtures thereof. However, the material of the cathode electrode CE is not limited thereto.

It may be understood that any one of the anode electrodes AE, a portion of the light emitting structure EMS, which overlaps the anode electrodes AE, and a portion of the cathode electrode CE, which overlaps the anode electrodes AE, constitute a light emitting element (e.g., single light emitting element) LD (see FIG. 5). In other words, each of light emitting elements of the sub-pixels may include one anode electrode AE, a portion of the light emitting structure EMS, which overlaps the anode electrodes AE, and a portion of the cathode electrode CE, which overlaps the anode electrodes AE. In each of the first to third sub-pixels SP1 to SP3, holes injected from the anode electrode AE and electrons injected from the cathode electrode CE may be transported into a light emitting layer of the light emitting structure EMS to form excitons, and light may be generated in case that the excitons are changed from an excited state to a ground state. A luminance of the light may be determined according to an amount of current flowing through the light emitting layer. A wavelength band of the generated light may be determined according to a configuration of the light emitting layer.

The encapsulation layer TFE may be disposed over the cathode electrode CE. The encapsulation layer TFE may cover the light emitting element layer LDL and/or the pixel circuit layer PCL. The encapsulation layer TFE may prevent oxygen and/or moisture from infiltrating into the light emitting element layer LDL. In embodiments, the encapsulation layer TFE may include a structure in which at least one inorganic layer and at least one organic layer are alternately stacked. For example, the inorganic layer may include silicon nitride, silicon oxide, silicon oxynitride (SiOₓN_{y}), or the like. For example, the organic layer may include an organic insulating material such as acrylic resin, epoxy resin, phenolic resin, polyamide resin, polyimide resin, unsaturated polyester resin, polyphenylene resin, polyphenylenesulfide resin, or benzocyclobutene (BCB). However, the materials of the organic layer and the inorganic layer of the encapsulation layer TFE are not limited thereto.

In order to improve encapsulation efficiency of the encapsulation layer TFE, the encapsulation layer TFE may further include a thin film including aluminum oxide (AlOₓ). The thin film including the aluminum oxide may be positioned on a top surface (or upper surface) of the encapsulation layer TFE, which faces the optical functional layer OFL, and/or a bottom surface (or lower surface) of the encapsulation layer TFE, which faces the light emitting element layer LDL.

The thin film including the aluminum oxide may be formed through an Atomic Layer Deposition (ALD) process. However, embodiments are not limited thereto. The encapsulation layer TFE may further include a thin film formed of at least one of various materials suitable for the improvement of the encapsulation efficiency.

The optical functional layer OFL may be disposed on the encapsulation layer TFE. The optical functional layer OFL may include a color filter layer CFL and a lens array LA.

The color filter layer CFL may be disposed between the encapsulation layer TFE and the lens array LA. The color filter layer CFL may filter light emitted from the light emitting structure EMS, thereby selectively outputting light of a wavelength band or a color, which corresponds to each sub-pixel. The color filter layer CFL may include color filters CF respectively corresponding to the sub-pixels. Each of the color filters CF may allow light having a wavelength band corresponding to a corresponding sub-pixel to pass therethrough. For example, a color filter corresponding to the first sub-pixel SP1 may allow light of a red color to pass therethrough, a color filter corresponding to the second sub-pixel SP2 may allow light of a green color to pass therethrough, and a color filter corresponding to the third sub-pixel SP3 may allow light of a blue color to pass therethrough. According to light emitted from the light emitting structure EMS in each sub-pixel, at least some of the color filters CF may be omitted.

The lens array LA may be disposed on the color filter layer CFL. The lens array LA may include lenses LS respectively corresponding to the sub-pixels. Each of the lenses LS may output light emitted from the light emitting structure EMS along an intended path, thereby improving light emission efficiency. The lens array LA may have a relatively high refractive index. For example, the lens array LA may have a refractive index higher than a refractive index of the overcoat layer OC. In embodiments, the lenses LS may include an organic material. In embodiments, the lenses LS may include an acryl-based material. However, the material of the lenses LS is not limited thereto.

In embodiments, as compared with the opening OP of the pixel defining layer PDL, at least some of the color filters CF of the color filter layer CFL and at least some of the lenses LS of the lens array LS may be shifted in a direction parallel to a plane defined by the first and second directions DR1 and DR2. Specifically, in a central area of the display area DA, the center portion of a color filter and the center portion of a lens may be aligned with (or overlap) the center portion of a corresponding opening OP of the pixel defining layer PDL. For example, in the central area of the display area DA, the opening OP of the pixel defining layer PDL may overlap (e.g., completely overlap) the corresponding color filter of the color filter layer CFL and the corresponding lens of the lens array LA. In an area of the display area DA, which is adjacent to the non-display area NDA, the center portion of a color filter and the center portion of a lens may be shifted in a planar direction from the center portion of an opening OP of the pixel defining layer PDL. For example, in the area of the display area DA, which is adjacent to the non-display area NDA, the opening OP of the pixel defining layer PDL may overlap (e.g., partially overlap) the corresponding color filter of the color filter layer CFL and the corresponding lens of the lens array LA. Accordingly, in the center portion of the display area DA, light emitted from the light emitting structure EMS may be effectively output in a normal direction of the display surface. At an outer portion of the display area DA, light emitted from the light emitting structure EMS may be effectively output in a direction inclined by a selected angle with respect to the normal direction of the display surface.

The overcoat layer OC may be disposed over the lens array LA. The overcoat layer OC may cover the optical functional layer OFL, the encapsulation layer TFE, the light emitting structure EMS, and/or the pixel circuit layer PCL. The overcoat layer OC may include various materials suitable for protecting lower layers thereof from foreign matters such as dust and moisture. For example, the overcoat layer OC may include at least one of an inorganic insulating layer and an organic insulating layer. For example, the overcoat layer OC may include epoxy, but embodiments are not limited thereto. The overcoat layer OC may have a refractive index lower than a refractive index of the lens array LA.

The cover window CW may be disposed on the overcoat layer OC. The cover window CW may protect lower layers thereof. The cover window CW may have a refractive index higher than the refractive index of the overcoat layer OC. The cover window CW may include glass, but embodiments are not limited thereto. For example, the cover window CW may be an encapsulation glass that protects components disposed thereunder. In other embodiments, the cover window CW may be omitted.

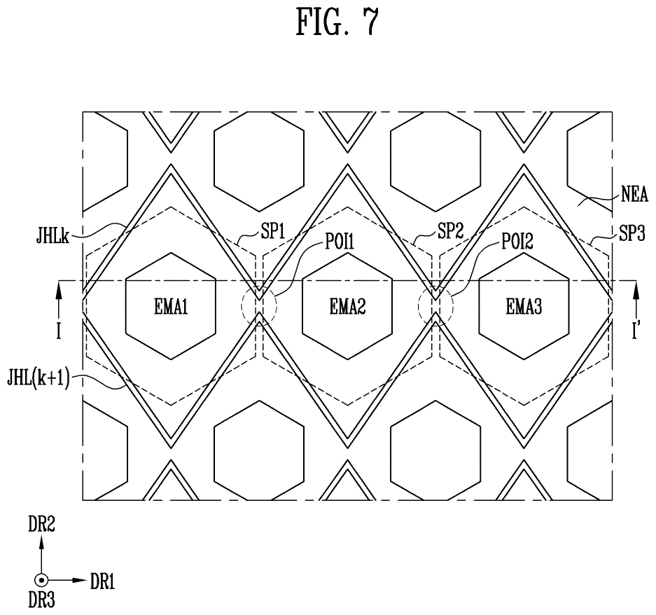

FIG. 7 is a schematic plan view illustrating a relationship between sub-pixels and metal lines.

Referring to FIG. 7, first to third sub-pixels SP1, SP2, and SP3 arranged in the first direction DR1 are illustrated. The first sub-pixel SP1 may include a first emission area EMA1 and a non-emission area NEA at the periphery of the first emission area EMA1. The second sub-pixel SP2 may include a second emission area EMA2 and the non-emission area NEA at the periphery of the second emission area EMA2. The third sub-pixel SP3 may include a third emission area EMA3 and the non-emission area NEA at the periphery of the third emission area EMA3.

The first emission area EMA1 may be an area in which light is emitted from a portion of a light emitting structure EMS (see FIG. 6), which corresponds to the first sub-pixel SP1. The second emission area EMA2 may be an area in which light is emitted from a portion of a light emitting structure EMS, which corresponds to the second sub-pixel SP2. The third emission area EMA3 may be an area in which light is emitted from a portion of a light emitting structure EMS, which corresponds to the third sub-pixel SP3. As described with reference to FIG. 6, each emission area may be understood as an opening of the pixel defining layer PDL, which corresponds to each of the first to third sub-pixels SP1 to SP3.

In FIG. 7, it is illustrated that the emission areas EMA1, EMA2, and EMA3 has a hexagonal shape. However, the emission areas EMA1, EMA2, and EMA3 may be formed in another polygonal shape including a quadrangular shape. For example, the emission areas EMA1, EMA2, and EMA3 may be formed in a circular shape or an elliptical shape. For example, shapes and areas of different emission areas EMA1, EMA2, and EMA3 may be the same or be different from one another.

Metal lines JHLk and JHL(k+1) may extend in the first direction DR1, and may have a shape surrounding corresponding emission areas EMA1, EMA2, and EMA3. For example, the metal lines JHLk and JHL(k+1) may extend in the first direction DR1, and may be extend in a zigzag shape.

However, since the metal lines JHLk and JHL(k+1) are not connected to each other on the display area DA, areas POI1 and POI2 which are not covered by the metal lines JHLk and JHL(k+1) may exist (or be disposed) between adjacent emission areas EMA1, EMA2, and EMA3. However, in the areas POI1 and POI2, two or more metal lines JHLk and JHL(k+1) may be disposed to be adjacent to each other at a minimum distance. In accordance with this embodiment, an organic material existing in the areas POI1 and POI2 which do not overlap the metal lines JHLk and JHL(k+1) may be sublimated due to heat generated in two adjacent metal lines JHLk and JHL(k+1), and thus a leakage current through the organic material may be prevented.

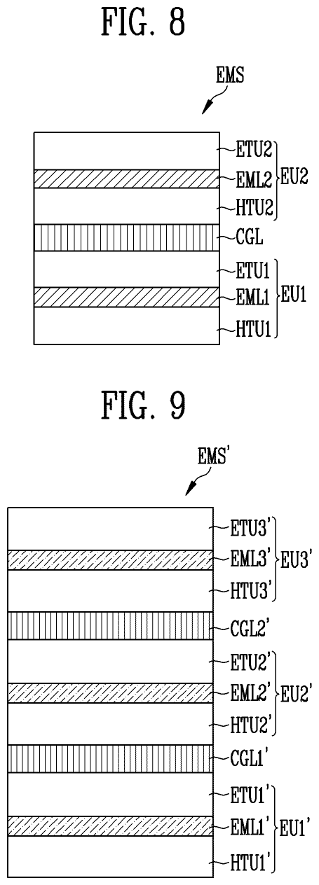

FIG. 8 is a schematic sectional view illustrating an embodiment of a light emitting structure.

Referring to FIG. 8, a light emitting structure EMS may have a tandem structure in which first and second light emitting units EU1 and EU2 are stacked.

Each of the first and second light emitting units EU1 and EU2 may include a light emitting layer generating light according to an applied current. The first light emitting unit EU1 may include a first light emitting layer EML1, a first electron transport unit ETU1, and a first hole transport unit HTU1. The first light emitting layer EML1 may be disposed between the first electron transport unit ETU1 and the first hole transport unit HTU1. The second light emitting unit EU2 may include a second light emitting layer EML2, a second electron transport unit ETU2, and a second hole transport unit HTU2. The second light emitting layer EML2 may be disposed between the second electron transport unit ETU2 and the second hole transport unit HTU2.

Each of the first and second hole transport units HTU1 and HTU2 may include at least one of a hole injection layer and a hole transport layer. Each of the first and second hole transport units HTU1 and HTU2 may further include a hole buffer layer, an electron blocking layer, and the like. The first and second hole transport units HTU1 and HTU2 may have the same configuration or have different configurations.

Each of the first and second electron transport units ETU1 and ETU2 may include at least one of an electron injection layer and an electron transport layer. Each of the first and second electron transport units ETU1 and ETU2 may further include an electron buffer layer, a hole blocking layer, and the like. The first and second electron transport units ETU1 and ETU2 may have the same configuration or have different configurations.

A connection layer, which is provided in the form of a charge generation layer CGL, may be disposed between the first light emitting unit EU1 and the second light emitting unit EU2 to connect the first light emitting unit EU1 and the second light emitting unit EU2 to each other. In embodiments, the charge generation layer CGL may have a stacked structure of a p-dopant layer and an n-dopant layer. For example, the p-dopant layer may include a p-type dopant such as HAT-CN, TCNQ or NDP-9, and the n-dopant layer may include an alkali metal, an alkali earth metal, a lanthanide-based metal, or any combination thereof. However, embodiments are not limited thereto.

In embodiments, the first light emitting layer EML1 and the second light emitting layer EML2 may generate lights of different colors. Lights respectively emitted from the first light emitting layer EML1 and the second light emitting layer EML2 may be mixed together, to be viewed as white light. For example, the first light emitting layer EML1 may generate light of a blue color, and the second light emitting layer EML2 may generate light of a yellow color. In embodiments, the second light emitting layer EML2 may include a structure in which a first sub-light emitting layer that generates light of a red color and a second sub-light emitting layer that generates light of a green color are stacked. The light of the red color and the light of the green color may be mixed together to provide the light of the yellow color. An intermediate layer, which performs a function of transporting holes and/or a function of blocking transportation of electrodes, may be further disposed between the first and second sub-light emitting layers.

In other embodiments, the first light emitting layer EML1 and the second light emitting layer EML2 may generate light of the same color.

In embodiments, the light emitting structure EMS may be formed through a process such as vacuum deposition or inkjet printing, but embodiments are not limited thereto.

FIG. 9 is a schematic sectional view illustrating another embodiment of the light emitting structure.

Referring to FIG. 9, a light emitting structure EMS′ may be a tandem structure in which first to third light emitting units EU1′ to EU3′ are stacked.

Each of the first to third light emitting units EU1′ to EU3′ may include a light emitting layer generating light according to an applied current. The first light emitting unit EU1′ may include a first light emitting layer EML1′, a first electron transport unit ETU1′ and a first hole transport unit HTU1′. The first light emitting layer EML1′ may be disposed between the first electron transport unit ETU1′ and the first hole transport unit HTU1′. The second light emitting unit EU2′ may include a second light emitting layer EML2′, a second electron transport unit ETU2′, and a second hole transport unit HTU2′. The second light emitting layer EML2′ may be disposed between the second electron transport unit ETU2′ and the second hole transport unit HTU2′. The third light emitting unit EU3′ may include a third light emitting layer EML3′, a third electron transport unit ETU3′, and a third hole transport unit HTU3′. The third light emitting layer EML3′ may be disposed between the third electron transport unit ETU3′ and the third hole transport unit HTU3′.

Each of the first to third hole transport units HTU1′ to HTU3′ may include at least one of a hole injection layer and a hole transport layer, and further include a hole buffer layer, and an electron blocking layer, and the like. The first to third hole transport units HTU1′ to HTU3′ may have the same configuration or have different configurations.

Each of the first to third electron transport units ETU1′ to ETU3′ may include at least one of an electron injection layer and an electron transport layer, and further include an electron buffer layer, a hole blocking layer, and the like. The first to third electron transport units ETU1′ to ETU3′ may have the same configuration or have different configurations.

A first charge generation layer CGL1′ may be disposed between the first light emitting unit EU1′ and the second light emitting unit EU2′. A second charge generation layer CGL2′ may be disposed between the second light emitting unit EU2′ and the third light emitting unit EU3′.

In embodiments, the first to third light emitting layers EML1′ to EML3′ may generate lights of different colors. Lights respectively emitted from the first to third light emitting layers EML1′ to EML3′ may be mixed together, to be viewed as white light. For example, the first light emitting layer EML1′ may generate light of a blue color, the second light emitting layer EML2′ may generate light of a green color, and the third light emitting layer EML3′ may generate light of a red color.

In other embodiments, light emitting layers of at least two of the first to third light emitting layers EML1′ to EML3′ may generate light of the same color.

Unlike as shown in FIGS. 8 and 9, a light emitting structure EMS of each sub-pixel may include one light emitting unit. Light emitting units included in different sub-pixels SP1, SP2, and SP3 adjacent to each other may emit lights of different colors. For example, a light emitting unit of the first sub-pixel SP1 may emit light of a red color, a light emitting unit of the second sub-pixel SP2 may emit light of a green color, and a light emitting unit of the third sub-pixel SP3 may emit light of a blue color. The light emitting units of the first to third sub-pixels SP1 to SP3 may be separated from each other, and each of the light emitting structures may be disposed in the opening OP of the pixel defining layer PDL. At least some of the color filters CF1 to CF3 may be omitted.

FIG. 10 is a schematic sectional view taken along line I-I′ shown in FIG. 7.

Referring to FIG. 10, a substrate SUB and a pixel circuit layer PCL disposed on the substrate SUB may be provided.

The substrate SUB may include a silicon wafer substrate formed using a semiconductor process. For example, the substrate SUB may include silicon, germanium, and/or silicon-germanium.

The pixel circuit layer PCL may be disposed on the substrate SUB. The substrate SUB and the pixel circuit layer PCL may include circuit elements of each of first to third sub-pixels SP1 to SP3. For example, the substrate SUB and the pixel circuit layer PCL may include a transistor T_SP1 of the first sub-pixel SP1, a transistor T_SP2 of the second sub-pixel SP2, and a transistor T_SP3 of the third sub-pixel SP3. The transistor T_SP1 of the first sub-pixel SP1 may be any one of transistors included in a sub-pixel circuit SPC (see FIG. 5) of the first sub-pixel SP1, the transistor T_SP2 of the second sub-pixel SP2 may be any one of transistors included in a sub-pixel circuit SPC of the second sub-pixel SP2, and the transistor T_SP3 of the third sub-pixel SP3 may be any one of transistors included in a sub-pixel circuit SPC of the third sub-pixel SP3. In FIG. 10, for clear and brief description, one of the transistors of each sub-pixel is illustrated, and the other circuit elements are omitted.

The transistors T_SP1 of the first sub-pixel SP1 may include a source region SRA, a drain region DRA, and a gate electrode GE.

The source region SRA and the drain region DRA may be disposed in the substrate SUB. A well WL formed through an ion implantation process may be disposed in the substrate SUB, and the source region SRA and the drain region DRA may be disposed in the well WL to be spaced apart from each other. A region between the source region SRA and the drain region DRA in the well WL may be defined as a channel region.

The gate electrode GE may overlap the channel region between the source region SRA and the drain region DRA, and be disposed in the pixel circuit layer PCL. The gate electrode GE may be spaced apart from the well WL or the channel region by an insulating material such as a gate insulating layer GI. The gate electrode GE may include a conductive material.

A plurality of layers included in the pixel circuit layer PCL may include insulating layers and conductive patterns disposed between the insulating layers, and the conductive patterns may include first and second conductive patterns CP1 and CP2. The first conductive pattern CP1 may be electrically connected to the drain region DRA through a drain connection portion DRC penetrating (or passing through) one or more insulating layers. The second conductive pattern CP2 may be electrically connected to the source region SRA through a source connection portion SRC penetrating (or passing through) one or more insulating layers.

As the gate electrode GE and the first and second conductive patterns CP1 and CP2 are connected to other circuit elements and/or lines, the transistor T_SP1 of the first sub-pixel SP1 may be provided as any one of the transistors of the first sub-pixel SP1.

Each of the transistor T_SP2 of the second sub-pixel SP2 and the transistor T_SP3 of the third sub-pixel SP3 may be formed in a manner identical or similar to the transistor T_SP1 of the first sub-pixel SP1. For example, auxiliary transistors ATR1, ATR2, and ATR3 of auxiliary circuits AC may be formed in a manner identical or similar to the transistor T_SP1 of the first sub-pixel SP1.

For example, the substrate SUB and the pixel circuit layer PCL may include the circuit elements of each of the first to third sub-pixels SP1 to SP3 and the auxiliary transistors ATR1, ATR2, and ATR3 of the auxiliary circuits AC. In another embodiment, the auxiliary transistors ATR1, ATR2, and ATR3 may be positioned in another layer in the third direction DR3 with respect to the transistors T_SP1, T_SP2, and T_SP3 of the first to third sub-pixels SP1 to SP3.

A via layer VIAL may be disposed on the pixel circuit layer PCL. The via layer VIAL may cover the pixel circuit layer PCL, and may have an entirely flat surface. The via layer VIAL may planarize step differences on the pixel circuit layer PCL. The via layer VIAL may include at least one of silicon oxide (SiOₓ), silicon nitride (SiNₓ), and silicon carbon nitride (SiCN), but embodiments are not limited thereto.

A light emitting element layer LDL may be disposed on the via layer VIAL. The light emitting element layer LDL may include first to third reflective electrodes RE1 to RE3, a planarization layer PLNL, first to third anode electrodes AE1 to AE3, a pixel defining layer PDL, a light emitting structure EMS, and a cathode electrode CE.

On the via layer VIAL, the first to third reflective electrodes RE1 to RE3 may be disposed in the first to third sub-pixels SP1 to SP3, respectively. Each of the first to third reflective electrodes RE1 to RE3 may be in contact with a circuit element disposed in the pixel circuit layer PCL through a via penetrating (or passing through) the via layer VIAL.

The first to third reflective electrodes RE1 to RE3 may function as full mirrors which reflect light emitted from the light emitting structure EMS toward a display surface (or a cover window CW). The first to third reflective electrodes RE1 to RE3 may include a metal material suitable for reflecting light. The first to third reflective electrodes RE1 to RE3 may include at least one of aluminum (Al), silver (Ag), magnesium (Mg), platinum (Pt), palladium (Pd), gold (Au), nickel (Ni), neodymium (Nd), iridium (Ir), chromium (Cr), titanium (Ti), and alloys of two or more materials selected therefrom, but embodiments are not limited thereto.

In embodiments, a connection electrode may be disposed on the bottom (or lower surface) of each of the first to third reflective electrodes RE1 to RE3. The connection electrode may improve an electrical connection characteristic between a corresponding reflective electrode and a circuit element of the pixel circuit layer PCL. The connection electrode may have a multi-layer structure. The multi-layer structure may include titanium (Ti), titanium nitride (TiN), tantalum nitride (TaN), and the like, but embodiments are not limited thereto. In embodiments, a corresponding reflective electrode may be positioned between multiple layers of the connection electrode.

A buffer pattern BFP may be disposed on the bottom (or lower surface) of at least one of the first to third reflective electrodes REI to RE3. The buffer pattern BFP may include an inorganic material such as silicon carbon nitride, but embodiments are not limited thereto. As the buffer pattern BFP is disposed, a height of the corresponding reflective electrode in the third direction DR3 may be controlled. For example, the buffer pattern BFP may be disposed between the first reflective electrode RE1 and the via layer VIAL, to control a height of the first reflective electrode RE1.

The first to third reflective electrodes RE1 to RE3 may function as full mirrors, and the cathode electrode CE may function as a half mirror. Light emitted from a light emitting layer of the light emitting structure EMS may be amplified by at least partially reciprocating between a corresponding reflective electrode and the cathode electrode CE, and the amplified light may be output through the cathode electrode CE. For example, a distance between each reflective electrode and the cathode electrode CE may be understood as a resonance distance of light emitted from the light emitting layer of the corresponding light emitting structure EMS.

By the buffer pattern BFP, the first sub-pixel SP1 may have a resonance distance shorter than a resonance distance of another sub-pixel. Light in a specific wavelength range (e.g., a red color) may be effectively and efficiently amplified by the adjusted resonance distance. Accordingly, the first sub-pixel SP1 may effectively and efficiently output light of the corresponding wavelength range.

In FIG. 10, it is illustrated the buffer pattern BFP is provided to the first sub-pixel SP1 and is not provided to the second and third sub-pixels SP2 and SP3. However, embodiments are not limited thereto. The buffer pattern may be provided even in at least one of the second and third sub-pixels SP2 and SP3, to adjust a resonance distance of the at least one of the second and third sub-pixels SP2 and SP3. For example, the first to third sub-pixels SP1 to SP3 may respectively correspond to red, green, and blue. A distance between the first reflective electrode RE1 and the cathode electrode CE may be shorter than a distance between the second reflective electrode RE2 and the cathode electrode CE, and the distance between the second reflective electrode RE2 and the cathode electrode CE may be shorter than a distance between the third reflective electrode RE3 and the cathode electrode CE.

The planarization layer PLNL may be disposed on the via layer VIAL and the first to third reflective electrodes RE1 to RE3 to planarize step differences between the first to third reflective electrodes RE1 to RE3. The planarization layer PLNL may cover (e.g., entirely cover) the first to third reflective electrodes RE1 to RE3 and the via layer VIAL, and may have a flat surface. In embodiments, the planarization layer PLNL may be omitted.

The first to third anode electrodes AE1 to AE3 respectively overlapping the first to third reflective electrodes RE1 to RE3 may be disposed on the planarization layer PLNL. The first to third anode electrodes AE1 to AE3 may have shapes similar to the first to third emission areas EMA1 to EMA3 shown in FIG. 7 when viewed in the third direction DR3. The first to third anode electrodes AE1 to AE3 may be electrically connected to the first to third reflective electrodes RE1 to RE3, respectively. The first anode electrode AE1 may be electrically connected to the first reflective electrode RE1 through a first via VIA1 penetrating (or passing through) the planarization layer PLNL. The second anode electrode AE2 may be electrically connected to the second reflective electrode RE2 through a second via VIA2 penetrating (or passing through) the planarization layer PLNL. The third anode electrode AE3 may be electrically connected to the third reflective electrode RE3 through a third via VIA3 penetrating (or passing through) the planarization layer PLNL.

In embodiments, the first to third anode electrodes AE1 to AE3 may include at least one of transparent conductive materials such as indium tin oxide (ITO), indium zinc oxide (IZO), zinc oxide (ZnOₓ), indium gallium zinc oxide (IGZO), and indium tin zinc oxide (ITZO), but embodiments are not limited thereto. However, the material of the first to third anode electrodes AE1 to AE3 is not limited thereto. For example, the first to third anode electrodes AE1 to AE3 may include titanium nitride.

In embodiments, insulating layers for adjusting a height of at least one of the first to third anode electrodes AE1 to AE3 may be further included. The insulating layers may be disposed between at least one of the first to third anode electrodes AE1 to AE3 and corresponding reflective electrodes. The planarization layer PLNL and/or the buffer pattern BFP may be omitted. For example, the first to third sub-pixels SP1 to SP3 may correspond to red, green, and blue, respectively, a distance between the first anode electrode AE1 and the cathode electrode CE may be shorter than a distance between the second anode electrode AE2 and the cathode electrode CE, and the distance between the second anode electrode AE2 and the cathode electrode CE may be shorter than a distance between the third anode electrode AE3 and the cathode electrode CE. The pixel defining layer PDL may be disposed on portions of the first to third anode electrodes AE1 to AE3 and the planarization layer PLNL. The pixel defining layer PDL may include an opening OP exposing a portion of each of the first to third anode electrodes AE1 to AE3. The opening OP of the pixel defining layer PDL may define an emission area of each of the first to third sub-pixels SP1 to SP3. For example, the pixel defining layer PDL may define the first to third emission areas EMA1 to EMA3 shown in FIG. 7, and may be disposed in the non-emission area NEA shown in FIG. 7.

In embodiments, the pixel defining layer PDL may include a plurality of inorganic insulating layers. Each of the plurality of inorganic insulating layers may include at least one of silicon oxide (SiOₓ) and silicon nitride (SiNₓ). For example, the pixel defining layer PDL may include first to third inorganic insulating layers, which are sequentially stacked, the first to third inorganic insulating layers may include silicon nitride, silicon oxide, and silicon nitride, respectively. However, embodiments are not limited thereto. The first to third inorganic insulating layers may have a stepped section in an area adjacent to the opening OP.

A metal line JHLk may be provided in a boundary area BDA between sub-pixels adjacent to each other. Each of metal lines JHL1 to JHLo including the metal line JHLk may be positioned on the pixel defining layer PDL (see FIG. 3).

Each of the metal lines JHL1 to JHLo including the metal line JHLk may be in contact with the cathode electrode CE of light emitting elements of sub-pixels SP in the display area DA. For example, as the metal lines JHL1 to JHLo generate heat due to Joule heating after the light emitting structure EMS is stacked, a portion of the light emitting structure EMS, which is positioned in the vicinity of each of the metal lines JHL1 to JHLo. In the case of the light emitting structure EMS shown in FIG. 8, as a Joule heating process is performed after the first light emitting unit EU1, the charge generation layer CGL, and the second light emitting unit EU2 are all stacked, the light emitting structure EMS may not remain on the metal line JHLk. In the case of the light emitting structure EMS shown in FIG. 9, as the Joule heating process is performed after the first light emitting unit EU1′, the first charge generation layer CGL1′, the second light emitting unit EU2′, the second charge generation layer CGL2′, and the third light emitting unit EU3′ are all stacked, the light emitting structure EMS′ may not remain on the metal line JHLk. Thus, a leakage current through portions of the light emitting structures EMS, which are cut by the metal lines JHL1 to JHLo, may be prevented. The metal lines JHL1 to JHLo may be exposed to the outside of the light emitting structure EMS, and be in contact with the cathode electrode CE which is deposited subsequently. As exemplified in FIG. 5, the reference voltage GND may be equal to the second power voltage VSS.

The light emitting structure EMS may be disposed on the anode electrodes AE exposed by the openings OP of the pixel defining layer PDL. In embodiments, the light emitting structure EMS may be formed through a process such as vacuum deposition or an inkjet printing. The light emitting structure EMS may fill the openings OP of the pixel defining layer PDL, and be disposed (e.g., entirely disposed) throughout the first to third sub-pixels SP1 to SP3. As described above, the light emitting structure EMS may be partially cut in the boundary area BDA by the metal line JHLk. Accordingly, in an operation of the display device 100, the magnitude of current leaked from each of the first to third sub-pixels SP1 to SP3 to a sub-pixel adjacent thereto through the layers included in the light emitting structure EMS may be decreased. Thus, first to third light emitting elements LD1 to LD3 may operate with a relatively high reliability.

The cathode electrode CE may be disposed over the light emitting structure EMS. The cathode electrode CE may be commonly provided in the first to third sub-pixels SP1 to SP3. The cathode electrode CE may function as a half mirror which allow light emitted from the light emitting structure EMS to be partially transmitted therethrough and to be partially reflected therefrom.

The first anode electrode AE1, a portion of the light emitting structure EMS, which overlaps the first anode electrode AE1, and a portion of the cathode electrode CE, which overlaps the first anode electrode AE1, may constitute the first light emitting element LD1. The second anode electrode AE2, a portion of the light emitting structure EMS, which overlaps the second anode electrode AE2, and a portion of the cathode electrode CE, which overlaps the second anode electrode AE2, may constitute the second light emitting element LD2. The third anode electrode AE3, a portion of the light emitting structure EMS, which overlaps the third anode electrode AE3, and a portion of the cathode electrode CE, which overlaps the third anode electrode AE3, may constitute the third light emitting element LD3.

An encapsulation layer TFE may be disposed over the cathode electrode CE. The encapsulation layer TFE may prevent oxygen and/or moisture from infiltrating into the light emitting element layer LDL.

An optical functional layer OFL may be disposed on the encapsulation layer TFE. In embodiments, the optical functional layer OFL may be attached to the encapsulation layer TFE through an adhesive layer APL. For example, the optical functional layer OFL may be separately manufactured to be attached to the encapsulation layer TFE through the adhesive layer APL. The adhesive layer APL may further perform a function of protecting lower layers including the encapsulation layer TFE.

The optical functional layer OFL may include a color filter layer CFL and a lens array LA. The color filter layer CFL may include first to third color filters CF1 to CF3 respectively corresponding to the first to third sub-pixels SP1 to SP3. The first to third color filters CF1 to CF3 may allow lights having different wavelength ranges to pass therethrough. For example, the first to third color filters CF1 to CF3 may allow red light, green light, and blue light to pass therethrough, respectively.

In embodiments, the first to third color filters CF1 to CF3 may overlap (e.g., partially overlap) each other in the boundary area BDA. In other embodiments, the first to third color filters CF1 to CF3 may be spaced apart from each other, and a black matrix may be provided between the first to third color filters CF1 to CF3.

The lens array LA may be disposed on the color filter layer CFL. The lens array LA may include first to third lenses LS1 to LS3 respectively corresponding to the first to third sub-pixels SP1 to SP3. The first to third lenses LS1 to LS3 may respectively output lights emitted from the first to third light emitting layers LD1 to LD3 along intended paths, thereby improving light emission efficiency.

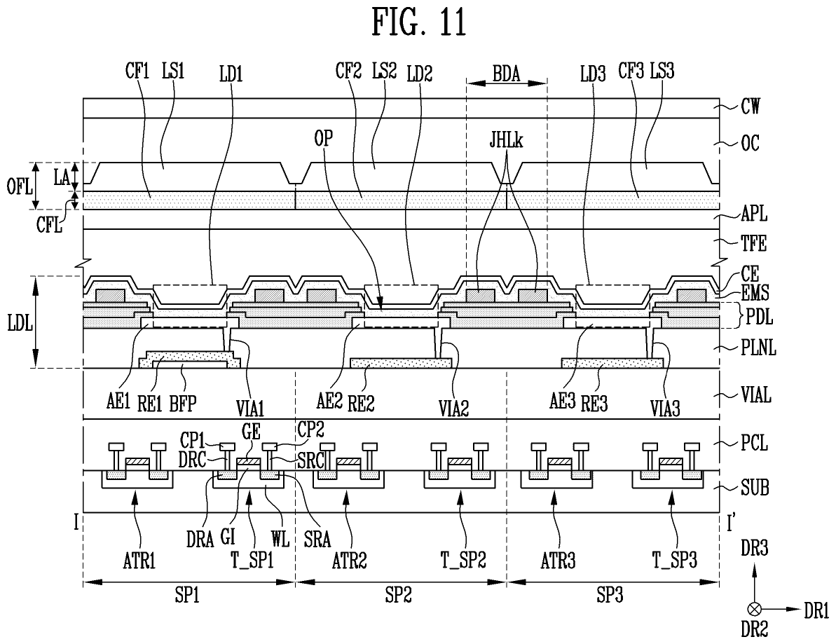

FIG. 11 is a schematic sectional view illustrating another embodiment of FIG. 10.

A light emitting structure EMS is different from the light emitting structure EMS shown in FIG. 10, in that a portion of the light emitting structure EMS remains on a metal line JHLk. For example, each of metal lines JHL1 to JHLo including the metal line JHLk may not be in contact with a cathode electrode CE of light emitting elements of sub-pixels SP in the display area DA.

For example, after the first light emitting unit EU1 and the charge generation layer CGL are stacked on the metal line JHLk, as heat due to Joule heating is generated from the metal line JHLk, portions of the first light emitting unit EU1 and the charge generation layer CGL, which are positioned in the vicinity of (or near) the metal line JHLk, may be sublimated. After that, stacking of the second light emitting unit EU2 may be performed (see FIG. 8). The metal line JHLk may be in contact with the remaining second light emitting unit EU2.

In another example, after the first light emitting unit EU1′, the first charge generation layer GL2′, the second light emitting unit EU2′, and the second charge generation layer CGL2′ are stacked on the metal line JHLk, as heat due to Joule heating is generated from the metal line JHLk, portions of the first light emitting unit EU1′, the first charge generation layer CGL1′, the second light emitting unit EU2′, and the second charge generation layer CGL2′, which are positioned in the vicinity of the metal line JHLk, may be sublimated. After that, stacking of the third light emitting unit EU3′ may be performed (see FIG. 9). The metal line JHLk may be in contact with the remaining third light emitting unit EU3′.

The charge generation layer CGL, the first charge generation layer CGL1′ or the second charge generation layer CGL2′, which have high conductivity, may be sublimated, and thus a leakage current may be prevented even in case that a portion of the light emitting structure EMS remains.

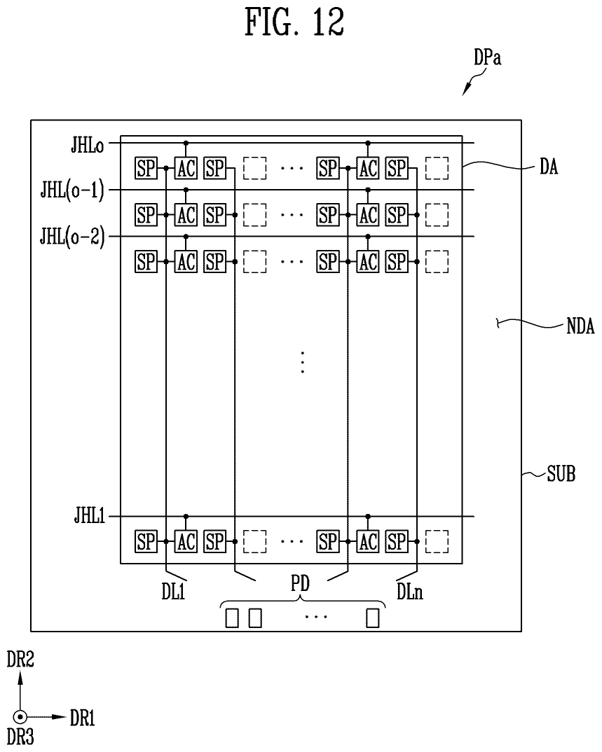

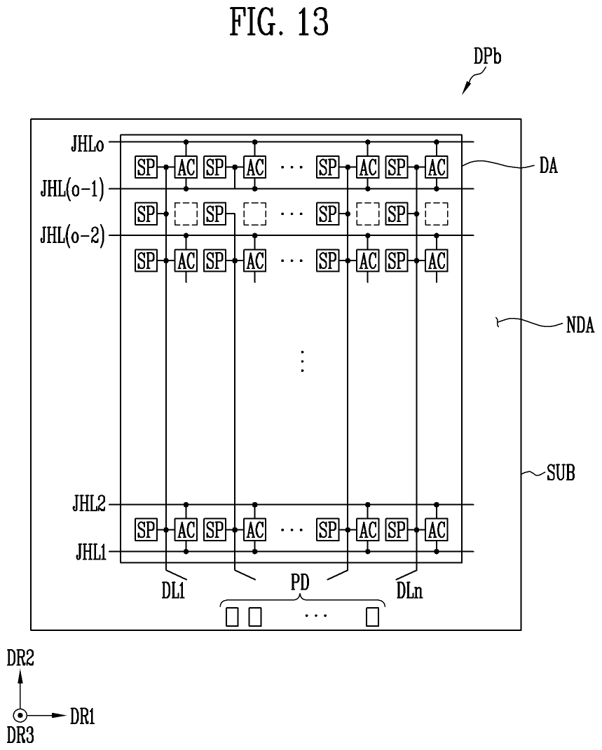

FIGS. 12 and 13 are schematic views illustrating other embodiments of the display panel shown in FIG. 3.

Referring to FIG. 12, a number of sub-pixels SP and a number of auxiliary circuits AC may be different from each other. For example, a number of auxiliary circuits AC of a display panel DPa may be smaller than a number of sub-pixels SP of the display panel DPa. For example, an auxiliary circuit (e.g., single auxiliary circuit) AC may be provided corresponding to a pixel (e.g., single pixel) PXL (see FIG. 1). For example, a number of pixels PXL and the number of auxiliary circuits AC may be the same as each other.

An area required to constitute the auxiliary circuits AC in the display area DA may be decreased, and thus the resolution of the sub-pixels SP may be increased.

Referring to FIG. 13, a number of sub-pixels SP and a number of auxiliary circuits AC may be different from each other. For example, a number of auxiliary circuits AC of a display panel DPb may be smaller than a number of sub-pixels SP.

Also, each of the auxiliary circuits AC may be connected to two or more metal lines JHL1, JHL2, . . . , JHL(o-2), JHL(0-1), and JHLo. For example, the auxiliary circuit AC may be connected to two metal lines adjacent to each other in the second direction DR2.

In an embodiment, the auxiliary circuits AC may be positioned on odd-numbered rows, and may not be positioned on even-numbered columns. In another example, the auxiliary circuits AC may be positioned on the even-numbered rows, and may not be positioned on the odd-numbered columns.

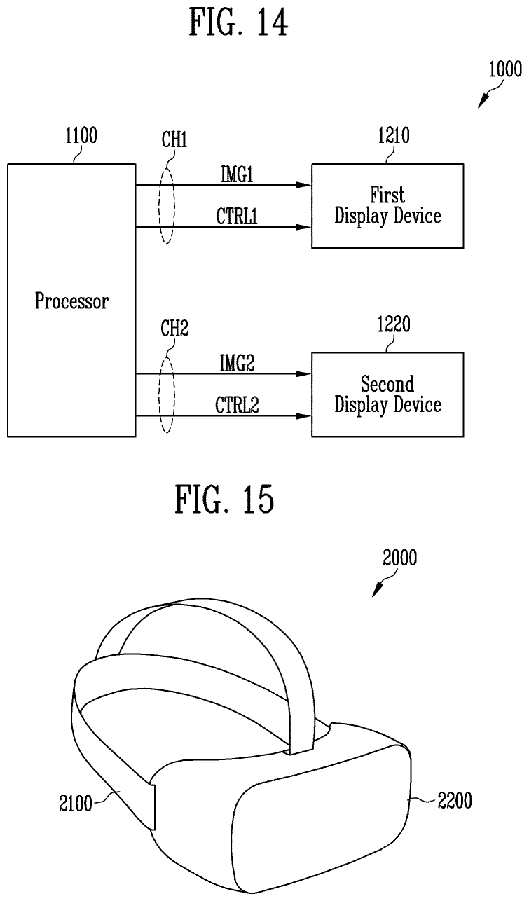

FIG. 14 is a schematic block diagram illustrating an embodiment of a display system.

Referring to FIG. 14, a display system 1000 may include a processor 1100 and one or more display devices 1210 and 1220.

The processor 1100 may perform various tasks and various calculations. In embodiments, the processor 1100 may include an Application Processor (AP), a Graphics Processing Unit (GPU), a microprocessor, a Central Processing Unit (CPU), and the like. The processor 1100 may be connected to other components of the display system 1000 through a bus system to control the components of the display system 1000.

In FIG. 14, it is illustrated that the display system 1000 includes first and second display devices 1210 and 1220. The processor 1100 may be connected to the first display device 1210 through a first channel CH1, and may be connected to the second display device 1220 through a second channel CH2.

Through the first channel CH1, the processor 1100 may transmit first image data IMG1 and a first control signal CTRL1 to the first display device 1210. The first display device 1210 may display an image, based on the first image data IMG1 and the first control signal CTRL1. The first display device 1210 may be formed in a manner identical or similar to the display device 100 described with reference to FIG. 1. The first image data IMG1 and the first control signal CTRL1 may be provided as the input image data IMG and the control signal CTRL, which are shown in FIG. 1, respectively.

Through the second channel CH2, the processor 1100 may transmit second image data IMG2 and a second control signal CTRL2 to the second display device 1220. The second display device 1220 may display an image, based on the second image data IMG2 and the second control signal CTRL2. The second display device 1220 may be formed in a manner identical or similar to the display device 100 described with reference to FIG. 1. The second image data IMG2 and the second control signal CTRL2 may be provided as the input image data IMG and the control signal CTRL, which are shown in FIG. 1, respectively.

The display system 1000 may include a computing system for providing an image display function, such as a portable computer, a mobile phone, a smartphone, a tablet personal computer (PC), a smart watch, a watch phone, a portable multimedia player (PMP), a navigation system, or an ultra mobile computer (UMPC). Also, the display system 1000 may include at least one of a head mounted display (HMD) device, a virtual reality (VR) device, a mixed reality (MR) device, and an augmented reality (AR) device.

FIG. 15 is a schematic perspective view illustrating an application example of the display system shown in FIG. 14.

Referring to FIG. 15, the display system 1000 shown in FIG. 14 may be applied to a head mounted display device 2000. The head mounted display device 2000 may be a wearable electronic device which is worn on a head of a user.

The head mounted display device 2000 may include a head mounting band 2100 and a display device accommodating case 2200. The head mounting band 2100 may be connected to the display device accommodating case 2200. The head mounting band 2100 may include a horizontal band and/or a vertical band, used to fix the head mounted display device 2000 to the head of the user. The horizontal band may surround a side portion of the head of the user, and the vertical band may surround an upper portion of the head of the user. However, embodiments are not limited thereto. For example, the head mounting band 2100 may be implemented in the form of a glasses frame, a helmet or the like.

The display device accommodating case 2200 may accommodate the first and second display devices 1210 and 1220 shown in FIG. 14. The display device accommodating case 2200 may further accommodate the processor 1100 shown in FIG. 14.

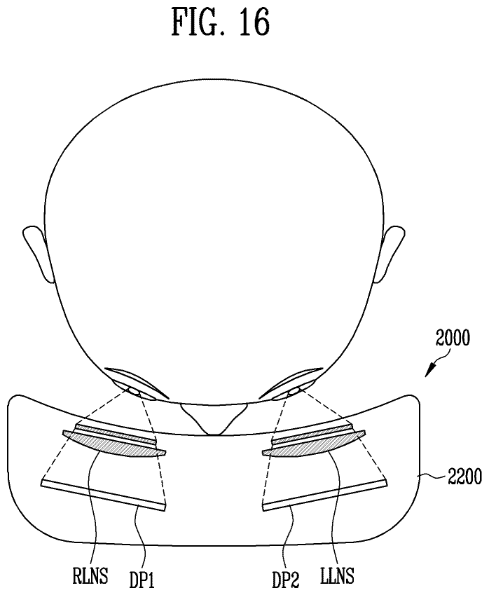

FIG. 16 is a schematic view illustrating a head-mounted display device shown in FIG. 15, which is worn by a user.

Referring to FIG. 16, a first display panel DPI of the first display device 1210 and a second display panel DP2 of the second display device 1220 may be disposed in the head mounted display device 2000. The head mounted display device 2000 may further include one or more lenses LLNS and RLNS.

In the display device accommodating case 2200, a right-eye lens RLNS may be disposed between the first display panel DPI and a right eye of the user. In the display device accommodating case 2200, a left-eye lens LLNS may be disposed between the second display panel DP2 and a left eye of the user.

An image output from the first display panel DPI may be viewed by the right eye of the user through the right-eye lens RLNS. The right-eye lens RLNS may refract light emitted from the first display panel DP1 to face the right eye of the user. The right-eye lens RLNS may perform an optical function for adjusting a viewing distance between the first display panel DP1 and the right eye of the user.

An image output from the second display panel DP2 may be viewed by the left eye of the user through the left-eye lens LLNS. The left-eye lens LLNS may refract light emitted from the second display panel DP2 to face the left eye of the user. The left-eye lens LLNS may perform an optical function for adjusting a viewing distance between the second display panel DP2 and the left eye of the user.

In embodiments, each of the right-eye lens RLNS and the left-eye lens LLNS may include an optical lens having a pancake-shaped section. In embodiments, each of the right-eye lens RLNS and the left-eye lens LLNS may include a multi-channel lens including sub-areas having different optical characteristics. Each display panel may output images respectively corresponding to the sub-areas of the multi-channel lens, and the output images may be viewed by the user while respectively passing through corresponding sub-areas.

In the display device and an electronic device in accordance with the disclosure, a leakage current through a common layer between adjacent pixels may be prevented.

In concluding the detailed description, those skilled in the art will appreciate that many variations and modifications may be made to the embodiments without substantially departing from the principles and spirit and scope of the disclosure. Therefore, the disclosed embodiments are used in a generic and descriptive sense only and not for purposes of limitation.

What is claimed is:

1. A display device comprising:
a substrate including a display area and a non-display area;
a sub-pixel disposed in the display area;
a metal line extending to be spaced apart from an emission area of the sub-pixel on a plane in the display area; and
an auxiliary circuit connected to the metal line in the display area,
wherein a sub-pixel circuit of the sub-pixel and the auxiliary circuit are connected to a same data line.

2. The display device of claim 1, wherein the auxiliary circuit includes an auxiliary transistor including a first electrode connected to the data line and a second electrode connected to the metal line.

3. The display device of claim 2, wherein a gate electrode of the auxiliary transistor is connected to the first electrode of the auxiliary transistor.

4. The display device of claim 3, wherein
the sub-pixel includes a light emitting element, and
a cathode electrode of the light emitting element and the second electrode of the auxiliary transistor are connected to a same voltage node.

5. The display device of claim 4, wherein the sub-pixel circuit includes:
a first transistor including:
a gate electrode connected to a first node,
a first electrode connected to a second node, and
a second electrode connected to an anode electrode of the light emitting element;
a second transistor including:
a gate electrode connected to a gate line,
a first electrode connected to the data line, and
a second electrode connected to the first node; and
a storage capacitor including:
a first electrode connected to a first power voltage node, and
a second electrode connected to the first node.

6. The display device of claim 5, wherein the sub-pixel circuit further includes:
a third transistor including:
a gate electrode connected to the second node,
a first electrode connected to the first power voltage node, and
a second electrode connected to the second node; and
a fourth transistor including:
a gate electrode and a first electrode, which are connected to the anode electrode of the light emitting element, and
a second electrode receiving a reference voltage.

7. The display device of claim 1, further comprising:
a pixel defining layer defining the emission area,
wherein the metal line is disposed on the pixel defining layer.

8. The display device of claim 1, wherein the sub-pixel circuit and the auxiliary circuit are disposed in a same pixel circuit layer.

9. A display device comprising:
a substrate including a display area and a non-display area;
sub-pixels disposed in the display area;
metal lines extending to be spaced apart from emission areas of the sub-pixels on a plane in the display area; and
auxiliary circuits connected to at least one of the metal lines in the display area,
wherein first sub-pixel circuits of first sub-pixels among the sub-pixels and first auxiliary circuits among the auxiliary circuits are connected to a same first data line.

10. The display device of claim 9, wherein
the metal lines extend in a first direction, and
the first data line extends in a second direction intersecting the first direction.

11. The display device of claim 9, wherein the first auxiliary circuits are connected to different metal lines.

12. The display device of claim 9, wherein each of the first auxiliary circuits is connected to two or more metal lines.

13. The display device of claim 9, wherein a number of the sub-pixels and a number of the auxiliary circuits are same as each other.

14. The display device of claim 9, wherein a number of the sub-pixels and a number of the auxiliary circuits are different from each other.

15. The display device of claim 14, wherein the number of the auxiliary circuits is smaller than the number of the sub-pixels.

16. The display device of claim 9, wherein each of the auxiliary circuits includes an auxiliary transistor including a first electrode connected to a data line and a second electrode connected to a metal line.

17. The display device of claim 16, wherein a gate electrode of the auxiliary transistor is connected to the first electrode of the auxiliary transistor.

18. The display device of claim 17, wherein
each of the sub-pixels includes a light emitting element, and
a cathode electrode of the light emitting element and the second electrode of the auxiliary transistor are connected to a same voltage node.

19. The display device of claim 18, wherein a sub-pixel circuit of each of the sub-pixels includes:
a first transistor including a gate electrode connected to a first node, a first electrode connected to a second node, and a second electrode connected to an anode electrode of the light emitting element;
a second transistor including a gate electrode connected to a gate line, a first electrode connected to a data line, and a second electrode connected to the first node; and
a storage capacitor including a first electrode connected to a first power voltage node and a second electrode connected to the first node.

20. The display device of claim 19, wherein the sub-pixel circuit further includes:
a third transistor including a gate electrode connected to the second node, a first electrode connected to the first power voltage node, and a second electrode connected to the second node; and
a fourth transistor including a gate electrode and a first electrode, which are connected to the anode electrode of the light emitting element, and a second electrode receiving a reference voltage.

21. An electronic device comprising:
a processor providing an image data; and
a display device displaying an image based on the image data, the display device comprising:
a substrate including a display area and a non-display area;
a sub-pixel disposed in the display area;
a metal line extending to be spaced apart from an emission area of the sub-pixel on a plane in the display area; and
an auxiliary circuit connected to the metal line in the display area,
wherein a sub-pixel circuit of the sub-pixel and the auxiliary circuit are connected to a same data line.
